(19) United States
(12) Patent Application Publication
(10) Pub. No.: US 2026/0182162 A1
(43) Pub. Date: Jun. 25, 2026

(54) DISPLAY PANEL AND ELECTRONIC APPARATUS INCLUDING THE SAME

(71) Applicant: Samsung Display Co., Ltd., Yongin-Si (KR)

(72) Inventors: Koichi SUGITANI, Yongin-si (KR); Gwuihyun Park, Yongin-si (KR); Hokyung Jang, Yongin-si (KR); Saehee Han, Yongin-si (KR)

(21) Appl. No.: 19/263,925

(22) Filed: Jul. 9, 2025

(30) Foreign Application Priority Data
Dec. 23, 2024 (KR) 10-2024-0194651

(51) Int. Cl. H10K 59/124; H10K 59/12

(52) U.S. Cl. CPC H10K 59/124; H10K 59/1201

(57) ABSTRACT

A display panel and an electronic apparatus including the display panel are provided. The display panel includes a substrate including a hole, a first area outside the hole, and a second area outside the first area, a first organic insulating layer disposed on the substrate in first and the second areas and including an end portion that is closest to the hole while the end portion has an upper portion extending beyond a lower portion of the end portion toward the hole, a second organic insulating layer disposed on the first organic insulating layer in the first and the second areas, and a display element disposed on the second organic insulating layer in the second area, and including a pixel electrode disposed on the second organic insulating layer.

### CROSS-REFERENCE TO RELATED APPLICATION

This application is based on, and claims priority under 35 U.S.C. § 119 to, Korean Patent Application No. 10-2024-0194651 filed on Dec. 23, 2024 in the Korean Intellectual Property Office, the disclosure of which is incorporated by reference herein in its entirety.

### BACKGROUND

### 1. Field

Embodiments relate to a display panel and an electronic apparatus including the display panel, and more particularly, to a display panel having a low defect rate and an electronic apparatus including the display panel.

### 2. Description of the Related Art

A display panel includes a display area and a peripheral area outside the display area. In electronic apparatuses including such display panels, the area of the display area is increasing, and various functions have been added to the electronic apparatuses. Accordingly, research has been conducted with display panels wherein various components may be arranged in the display area and electronic apparatuses including the display panels.

### SUMMARY

In a display panel of the related art and an electronic apparatus including the display panel, a defect frequently occurs during the manufacturing process or while the display panels or the electronic apparatuses are in use.

Embodiments include a display panel having a low defect rate and an electronic apparatus including the display panel. However, the above objective is just an example, and the scope of the disclosure is not limited thereto.

Additional aspects will be set forth in part in the description which follows and, in part, will be apparent from the description, or may be learned by practice of the presented embodiments of the disclosure.

According to embodiments, a display panel includes a substrate including a hole, a first area outside the hole, and a second area outside the first area, a first organic insulating layer disposed over the substrate in the first area and the second area, an end portion that is closest to the hole and having an upper portion extending beyond a lower portion of the end portion toward the hole, a second organic insulating layer disposed on the first organic insulating layer in the first area and the second area, and a display element that is disposed on the second organic insulating layer in the second area and includes a pixel electrode disposed on the second organic insulating layer.

An end of the second organic insulating layer that is closest to the hole may be disposed on the first organic insulating layer.

The display panel may further include a mask conductive layer disposed on the second organic insulating layer, located in the first area, and including a same material as the pixel electrode.

The mask conductive layer may be surrounded by different material.

In a view from a direction perpendicular to the substrate, the mask conductive layer may surround the hole.

In a view from the direction perpendicular to the substrate, the mask conductive layer may have a ring shape such that the hole is located inside of the mask conductive layer.

An end of the mask conductive layer that is closest to the hole may be disposed on the second organic insulating layer.

The display panel may further include an inorganic insulating layer disposed on the substrate in the first area and the second area and interposed between the substrate and the first organic insulating layer, wherein the inorganic insulating layer includes a first portion located between the first organic insulating layer and the hole and a second portion located between the first portion and the hole, and a thickness of the second portion is less than a thickness of the first portion.

The display panel may further includes a mask conductive layer disposed on the second organic insulating layer to be located in the first area and including a same material as the pixel electrode, an inorganic insulating layer disposed on the substrate in the first area and the second area and interposed between the substrate and the first organic insulating layer, a first metal layer disposed on the inorganic insulating layer and located between the hole and the end portion of the first organic insulating layer that is closest to the hole, a first additional organic insulating layer covering an edge of the first metal layer that is closest to the first organic insulating layer and spaced apart from the first organic insulating layer, a second additional organic insulating layer covering an edge of the first metal layer that is closest to the hole and spaced apart from the first additional organic insulating layer, a first additional mask conductive layer disposed on the first additional organic insulating layer, a second additional mask conductive layer disposed on the second additional organic insulating layer, and a second metal layer disposed on the first metal layer and located between the first additional mask insulating layer and the second additional mask insulating layer to be spaced apart from the first additional mask insulating layer and the second additional mask insulating layer.

A width of an upper portion of the second metal layer may be greater than a width of a lower portion of the second metal layer.

In a view from a direction perpendicular to the substrate, a gap between the first additional organic insulating layer and the second additional organic insulating layer may surround the hole.

In a view from a direction perpendicular to the substrate, each of the first metal layer and the second metal layer may surround the hole.

In a view from a direction perpendicular to the substrate, an end of the first additional mask conductive layer that is closest to the second additional mask conductive layer may be disposed on the first metal layer.

In a view from a direction perpendicular to the substrate, an end of the first additional mask that is closest to the second additional mask conductive layer may coincide with an end of the first metal layer that is closest to the first organic insulating layer.

In a view from a direction perpendicular to the substrate, an end of the second additional mask conductive layer that is closest to the first additional mask conductive layer may be disposed on the first metal layer.

In a view from a direction perpendicular to the substrate, an end of the second additional mask conductive layer that is closest to the first additional mask conductive layer may coincide with an end of the first metal layer that is closest to the hole.

The first additional mask conductive layer and the second additional mask conductive layer each may include a same material as the mask conductive layer.

The first additional organic insulating layer and the second additional organic insulating layer each may include a same material as the first organic insulating layer.

One or more embodiments relate to an electronic apparatus including a processor and a display panel configured to be controlled by the processor, and the display panel may include a substrate including a hole, a first area outside the hole, and a second area outside the first area, a first organic insulating layer disposed on the substrate in the first area and the second area, an end portion that is closest to the hole having an upper portion extending beyond a lower portion of the end portion toward the hole, a second organic insulating layer disposed on the first organic insulating layer in the first area and the second area, and a display element that is disposed on the second organic insulating layer in the second area and includes a pixel electrode disposed on the second organic insulating layer.

The electronic apparatus may further include an inorganic insulating layer disposed over the substrate in the first area and the second area and interposed between the substrate and the first organic insulating layer, wherein the inorganic insulating layer includes a first portion located between the first organic insulating layer and the hole and a second portion located between the first portion and the hole, and a thickness of the second portion is less than a thickness of the first portion.

Other aspects, features, and advantages than those described above will become apparent from the following drawings, claims, and detailed description of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a perspective view schematically illustrating an electronic apparatus according to an embodiment;

FIG. 2 is an exploded perspective view schematically illustrating the electronic apparatus of FIG. 1;

FIG. 3 is a block diagram schematically illustrating the electronic apparatus of FIG. 1;

FIG. 4 is a plan view schematically illustrating a display panel according to an embodiment;

FIG. 5 is a side view schematically illustrating the display panel of FIG. 4;

FIG. 6 is a cross-sectional view of the display panel taken along line A-A′ of FIG. 4;

FIG. 7 is a cross-sectional view of the display panel of FIG. 4 taken along a line perpendicular to line A-A′;

FIG. 8 is a plan view schematically illustrating a display panel included in the electronic apparatus of FIG. 1;

FIG. 9 is an equivalent circuit diagram of a pixel circuit electrically connected to a light-emitting diode included in the display panel of FIG. 8;

FIG. 10 is a plan view schematically illustrating a portion of the display panel of FIG. 8;

FIG. 11 is a cross-sectional view schematically illustrating a cross-section taken along line B-B′ of the display panel of FIG. 10;

FIGS. 12 through 17 are cross-sectional views schematically illustrating manufacturing operations of a display panel according to one embodiment;

FIG. 18 is a cross-sectional view schematically illustrating a portion of a display panel during the manufacturing process of the display panel, according to one embodiment;

FIG. 19 is a cross-sectional view schematically illustrating a portion of a display panel according to one embodiment;

FIGS. 20 through 23 are cross-sectional views schematically illustrating manufacturing operations of a display panel according to one embodiment;

FIG. 24 is a cross-sectional view schematically illustrating a portion of a display panel according to one embodiment; and

FIG. 25 is a cross-sectional view schematically illustrating a portion of a display panel according to one embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the disclosure allows for various changes and numerous embodiments, particular embodiments will be illustrated in the drawings and described in detail in the written description. Effects and features of the disclosure and methods of achieving the same will be apparent with reference to embodiments and drawings described below in detail. The disclosure may, however, be embodied in many different forms and should not be construed as being limited to the embodiments set forth herein.

Hereinafter, embodiments of the disclosure will be described in detail with reference to the accompanying drawings, and in the description with reference to the drawings, the same or corresponding components are indicated by the same reference numerals and redundant descriptions thereof are omitted.

In the following embodiments, when an element, such as a layer, a film, a region, or a plate, is referred to as being “on” another element, the element can be directly on the other element, or intervening elements may be present therebetween. Also, sizes of elements in the drawings may be exaggerated or reduced for convenience of descriptions. For example, because sizes and thicknesses of elements in the drawings are arbitrarily illustrated for convenience of descriptions, the following embodiments are not limited thereto.

In the following embodiments, the x-axis, the y-axis, and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

In the following embodiments, while terms such as “first” and “second” are used to describe various elements, these elements are not limited by these terms. These terms are only used to distinguish one element from another element.

In the following embodiments, terms such as “include,” “comprise,” and “have” specify the presence of stated features or elements, but do not preclude the presence or addition of one or more other features or elements.

In the present specification, the expression “A and/or B” represents just A, just B, or A and B. Also, the expression “at least one of A and B” represents just A, just B, or A and B.

In the following embodiments, when a layer, region, or element is referred to as being “connected to” another layer, region, or element, it can be directly or indirectly connected to the other layer, region, or element. For example, intervening layers, regions, or elements may be present. For example, when a layer, region, or element is referred to as being “electrically connected to” or “electrically coupled to” another layer, region, or element, it can be directly or indirectly electrically connected or coupled to the other layer, region, or element. For example, intervening layers, regions, or elements may be present.

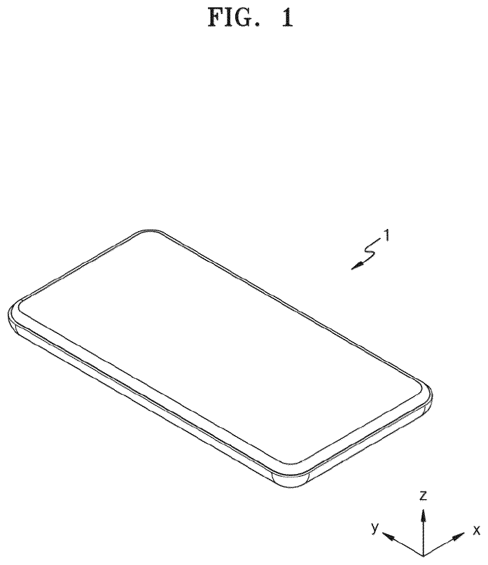

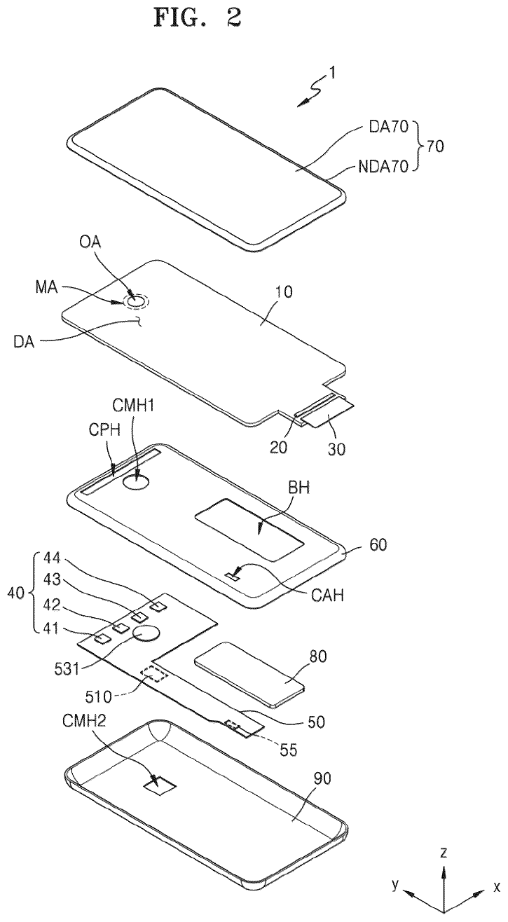

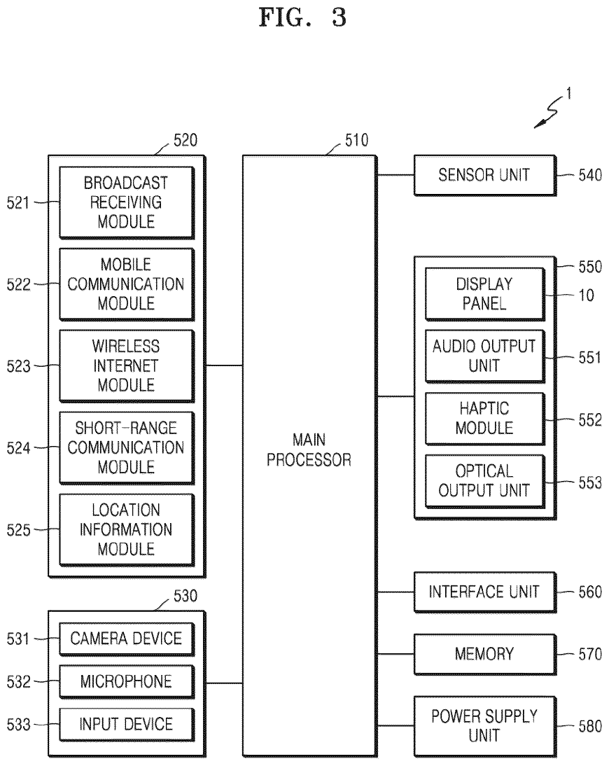

FIG. 1 is a perspective view schematically illustrating an electronic apparatus 1 according to an embodiment, FIG. 2 is an exploded perspective view schematically illustrating the electronic apparatus 1 of FIG. 1, and FIG. 3 is a block diagram schematically illustrating the electronic apparatus 1 of FIG. 1.

Referring to FIGS. 1 and 2, the electronic apparatus 1, which is a device that incorporates a display panel that displays moving images or still images, may be a portable electronic apparatus, such as a mobile phone, a smartphone, a tablet personal computer (PC), a mobile communication terminal, an electronic notebook, an electronic book, a portable multimedia player (PMP), a navigation device, or an ultra-mobile PC (UMPC), or may be used in a variety of products, such as televisions, laptops, monitors, billboards, or Internet of things (IoT). The electronic apparatus 1 according to an embodiment may also be a wearable device such as a smart watch, a watch phone, a glasses-type display, or a head-mounted display (HMD). The electronic apparatus 1 according to an embodiment may also be an instrument panel of a vehicle, a center fascia of a vehicle or a center information display (CID) disposed on a dashboard, a room mirror display replacing a side view mirror of a vehicle, or a display disposed on the rear side of a front seat as an entertainment device for a passenger in the backseat of a vehicle.

In FIGS. 1 and 2, for convenience of descriptions, the electronic apparatus 1 according to an embodiment is illustrated as a smartphone. The electronic apparatus 1 may include a cover window 70, a display panel 10, a data driver 20, a display circuit board 30, a component 40, a bracket 60, a main circuit board 50, a battery 80, and/or a lower cover 90.

In a plan view of this specification, “left,” “right,” “up,” and “down” indicate directions when the display panel 10 is viewed from a direction perpendicular to the display panel 10. For example, “left” indicates a −x direction, “right” indicates a +x direction, “up” indicates a +y direction, and “down” indicates a −y direction.

The electronic apparatus 1 may appear to have an approximately rectangular shape in a plan view. For example, as shown in FIG. 1, the electronic apparatus 1 may have an approximately rectangular shape having a short side in the x-axis direction and a long side in the y-axis direction in the xy-plane. A corner at which the short side in the x-axis direction meets the long side in the y-axis direction may be rounded with a certain curvature or formed at a right angle. The planar shape of the electronic apparatus 1 is not limited to a rectangle, and may include other polygonal, elliptical, or irregular shapes.

The cover window 70 may be disposed over the display panel 10 to cover an upper surface of the display panel 10. The cover window 70 may protect the upper surface of the display panel 10.

The cover window 70 may include a transparent cover unit DA70 corresponding to the display panel 10 and a light-shielding cover unit NDA70 surrounding the transparent cover unit DA70. Light from the display area DA of the display panel 10 may pass through the transparent cover unit DA70 and proceed to the outside. The light-shielding cover unit NDA70 may include an opaque material (e.g., a colored opaque material) that blocks light. The light-shielding cover unit NDA70 may include a pattern that is visible to the user when no image is displayed.

The cover windows 70 may include glass or plastic. If the cover window 70 includes glass, the cover window 70 may include ultra-thin glass. If the cover window 70 includes plastic, the cover window 70 may include polyethersulfone, polyacrylate, polyether imide, polyethylene naphthalate, polyethylene terephthalate, polyphenylene sulfide, polyarylate, polyimide, polycarbonate, or cellulose acetate propionate.

The display panel 10 may be disposed below the cover window 70. The display panel 10 may overlap the transparent cover unit DA70 of the cover window 70. The display panel 10 may include a display area DA. The display area DA is an area where an image may be displayed. The display area DA may include an area (hereinafter, component area) that transmits light emitted from a component 40 or a camera 531 disposed below the display panel 10 or transmits light proceeding toward the component 40 or the camera 531. In an alternative description, the display area DA may be referred to as being outside the component area to surround the component area. The component 40 may include a sensor that uses visible light, infrared light, sound, etc.

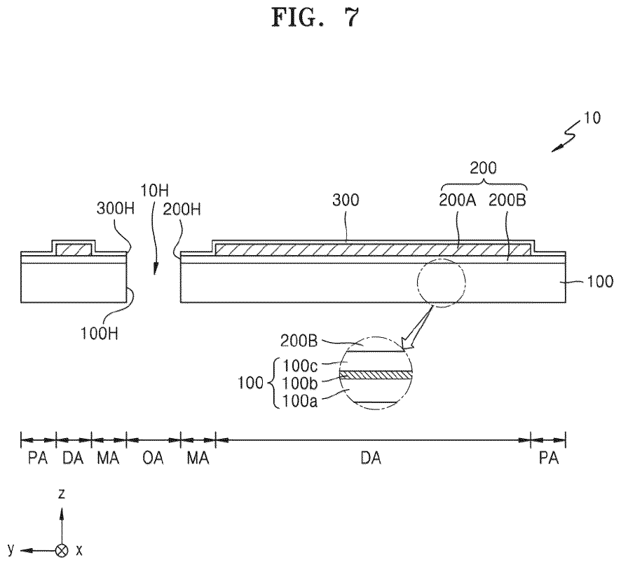

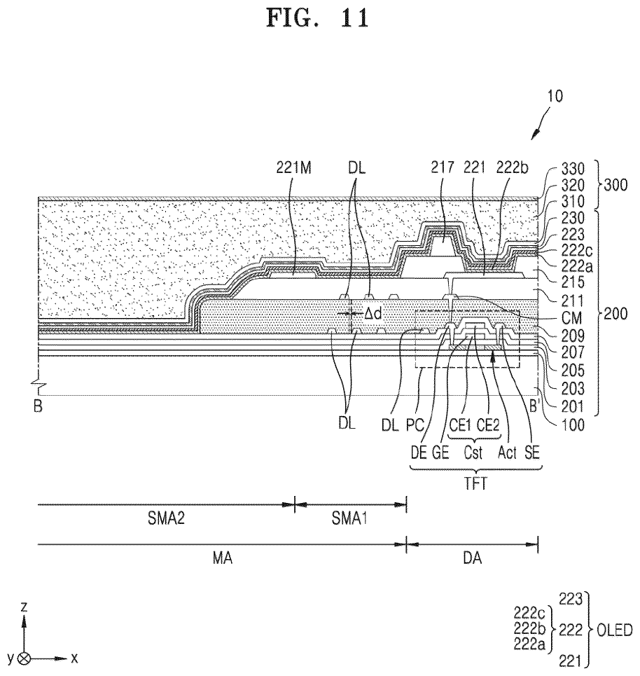

An opening area OA may be located within the display area DA. The opening area OA may be defined by an opening defined in a substrate 100 (see FIGS. 7 and 11) included in the display panel 10. The opening area OA may be located in the upper center of the display area DA as shown in FIG. 2, and the display area DA outside the opening area OA may surround the opening area OA. In one or more embodiments, the opening area OA may be located within the display area DA in various ways, such as being located at an upper left portion of the display area DA or at an upper right portion of the display area DA. Although FIG. 2 shows one opening area OA located within the display area DA, the display panel 10 may have a plurality of opening areas OA.

The component area described above may be or include the opening area OA. FIG. 2 shows that the location of the opening area OA corresponds to the location of the camera 531 disposed below the display panel 10. For example, in plan view, the opening area OA may overlap the camera 531. In one or more embodiments, the location of the opening area OA may correspond to the location of at least a part of the component 40, if necessary. For example, in the plan view, the opening area OA may overlap at least one of the first component 41, the second component 42, the third component 43, and the fourth component 44 included in the component 40. Hereinbelow, for convenience of descriptions, it is described that the location of the opening area OA corresponds to the location of the camera 531 disposed below the display panel 10.

An intermediate area MA, which may be referred to as a first area, may be located between the display area DA and the opening area OA. For example, the intermediate area MA, which may be referred to as the first area, may be located outside the opening area OA. The intermediate area MA may have a closed loop shape that entirely surrounds the opening area OA in the plan view. The display area DA may be referred to as a second area outside the first area.

The display panel 10 may be a light-emitting display panel including a light-emitting diode. The light-emitting diode may be an organic light-emitting diode (OLED) including an organic light-emitting layer (an organic emission layer) or an inorganic light-emitting diode including an inorganic material. The inorganic light-emitting diode may include a PN diode including inorganic semiconductor-based materials. When a voltage is applied in a forward direction to a PN junction diode, holes and electrons may be injected, and energy generated by recombination of the holes and electrons may be converted into light energy so that light in a certain wavelength range is emitted. The inorganic light-emitting diode described above may have a width of several to several hundred micrometers. The inorganic light-emitting diodes may be referred to as micro light-emitting diodes (LEDs).

The display panel 10 may be a rigid display panel that is not easily bendable or a flexible display panel that is easily bendable, foldable, or rollable. For example, the display panel 10 may be a foldable display panel, a curved display panel with a curved display surface, a bended display panel in which an area other than a display surface is bent, a rollable display panel that may be rolled or unrolled, or a stretchable display panel.

The display panel 10 may be a transparent display panel that allows an object or background in a rear side of the display panel 10 to be visible from a front side of the display panel 10. Alternatively, the display panel 10 may be a reflective display panel capable of reflecting light from an object in front of the display panel 10 or light from the background in the rear side of the display panel 10.

The data driver 20 may be mounted on the display panel 10 in the form of an integrated circuit (IC). In another embodiment, the data driver 20 may be disposed on the display circuit board 30.

The display circuit board 30 may be affixed to one side of the display circuit board 30. The display circuit board 30 may be a flexible printed circuit board (FPCB) that may be bent, a rigid printed circuit board (PCB) that is hard and is not easily bendable, or a composite printed circuit board including both an FPCB and a rigid PCB. A touch sensor driving unit may be mounted on the display circuit board 30. The touch sensor driving unit may be formed as an IC. The touch sensor driving unit may be electrically connected to touch electrodes of a touch screen layer of the display circuit board 30 through the display circuit board 30.

The touch screen layer of the display panel 10 may detect a user's touch input by using at least one of various touch methods such as a resistive film method and an electrostatic capacitance method. When the touch screen layer of the display panel 10 detects a user's touch input in an electrostatic capacitive manner, the touch sensor driving unit may apply driving signals to driving electrodes of the touch electrodes and detect, through sensing electrodes of the touch electrodes, voltages charged in mutual electrostatic capacitances (hereinafter, referred to as “mutual capacitance”) between the driving electrodes and the sensing electrodes, thereby determining whether a user's touch is received.

The user's touch may include a contact touch and a proximity touch. The contact touch indicates that a user's finger or an object such as a pen is in direct contact with the cover window 70 disposed on the touch screen layer. The proximity touch indicates that a user's finger or an object such as a pen is positioned close to the cover window 70, such as hovering. The touch sensor driving unit may transmit sensor data to a main processor 510 according to the detected voltages, and the main processor 510 may analyze the sensor data and calculate touch coordinates at which a touch input has occurred.

A control unit for supplying a driving voltage for driving pixels of the display panel 10, a gate driver, and the data driver 20 may be disposed on the display circuit board 30.

The bracket 60 for supporting the display panel 10 may be disposed below the display panel 10. The bracket 60 may include plastic, metal, or both plastic and metal. The bracket 60 may have a first camera hole CMH1 into which the camera 531 is inserted, a battery hole BH in which the battery 80 is disposed, a cable hole CAH through which a cable connected to the display circuit board 30 passes, and a component hole CPH corresponding to components 40. The component hole CPH may overlap the components 40 of the main circuit board 50 when viewed from a third direction (z-axis direction). For reference, the display area DA of the display panel 10 may overlap the components 40 of the main circuit board 50 when viewed from the third direction (z-axis direction). In another embodiment, the bracket (60) may not have a component hole (CPH).

The components 40 of the electronic apparatus 1 may include a first component 41, a second component 42, a third component 43, and a fourth component 44 that overlap the display panel 10. Each of the first component 41, the second component 42, the third component 43, and the fourth component 44 may include at least one of a proximity sensor, an illumination sensor, an iris sensor, a face recognition sensor, and a camera (or image sensor). The proximity sensor using infrared rays may detect an object disposed close to an upper surface of the electronic apparatus 1, and the illumination sensor may detect brightness of light incident on the upper surface of the electronic apparatus 1. In addition, the iris sensor may photograph a person's iris over the upper surface of the electronic apparatus 1, and the camera may photograph an object disposed over the upper surface of the electronic apparatus 1. The components 40 are not limited to a proximity sensor, an illumination sensor, an iris sensor, a face recognition sensor, and a camera, and may include various sensors.

The main circuit board 50 and the battery 80 may be disposed below the bracket 60. The main circuit board 50 may be a printed circuit board or a FPCB.

The main circuit board 50 may include the main processor 510, the camera 531, a main connector 55, and the components 40. The main processor 510 may be formed as an IC. When necessary, the electronic apparatus 1 may include not only the camera 531 disposed over the upper surface of the main circuit board 50 but also a camera disposed below a lower surface of the main circuit board 50. Each of the main processor 510 and the main connector 55 may be disposed on either one of the upper and lower surfaces of the main circuit board 50. The main circuit board 50 may be electrically connected to the display circuit board 30 through the main connector 55, etc.

The main processor 510 may control all functions of the electronic apparatus 1. For example, the main processor 510 may output digital video data to the data driver 20 so that an image is displayed on the display panel 10. The main processor 510 may control the display panel 10 in this way or in other ways. The main processor 510 may receive input of sensing data from the touch sensor driving unit. The main processor 510 may determine whether a user's touch is received according to the sensing data, and execute an operation corresponding to a direct touch or proximity touch of the user. The main processor 510 may be an application processor, a central processing unit, or a system chip, each of which includes an IC.

The camera 531 may process image frames of a still image, a moving image, or the like obtained by an image sensor in a camera mode, and output the processed image frames to the main processor 510. The camera 531 may include at least one of a camera sensor (e.g., charge-coupled device (CCD), complementary metal-oxide-semiconductor (CMOS), or the like), a photo sensor (or image sensor), or a laser sensor.

The cable, which passes through the cable hole CAH defined in the bracket 60, may be connected to the main connector 55, and thus the main connector 55 may be electrically connected to the display circuit board 30.

The electronic apparatus 1 may be represented by a block diagram as shown in FIG. 3. The electronic apparatus 1 may be represented as including, in addition to the main processor 510, a wireless communication unit 520, an input unit 530, a sensor unit 540, an output unit 550, an interface unit 560, a memory 570, and/or a power supply unit 580 shown in FIG. 3.

The wireless communication unit 520 may include at least one of a broadcast receiving module 521, a mobile communication module 522, a wireless Internet module 523, a short-range communication module 524, or a location information module 525.

The broadcast receiving module 521 may receive broadcast signals and/or broadcast-related information from an external broadcast management server via a broadcast channel. The broadcast channel may include satellite channels and terrestrial channels.

The mobile communication module 522 may transmit and receive wireless signals to and from at least one of, an external terminal, a server on a mobile communication network, or a base station established according to technology standards or communication methods for mobile communication (e.g., Global System for Mobile Communication (GSM), Code Division Multi Access (CDMA), Code Division Multi Access 2000 (CDMA2000), Enhanced Voice-Data Optimized or Enhanced Voice-Data Only (EV-DO), Wideband CDMA (WCDMA), High Speed Downlink Packet Access (HSDPA), High Speed Uplink Packet Access (HSUPA), Long Term Evolution (LTE), and Long Term Evolution-Advanced (LTE-A)). The wireless signal may include voice call signals, video call signals, or various forms of data according to text/multimedia message transmission and reception.

The wireless Internet module 523 is a module for wireless Internet connection. The wireless Internet module 523 may be configured to transmit and receive wireless signals in a communication network according to wireless Internet technologies. The wireless Internet technology may include, for example, Wireless LAN (WLAN), Wireless-Fidelity (Wi-Fi), Wi-Fi Direct, Digital Living Network Alliance (DLNA), and the like.

The short-range communication module 524, which ensures short-range communication, may support short-range communication by using at least one of Bluetooth, Radio Frequency Identification (RFID), Infrared Data Association (IrDA), Ultra-Wideband (UWB), ZigBee, Near Field Communication (NFC), Wi-Fi, Wi-Fi Direct, or Wireless Universal Seral Bus (USB) technologies. The short-range communication module 524 may support wireless communication between the electronic apparatus 1 and a wireless communication system, between the electronic apparatus 1 and another electronic apparatus, or the electronic apparatus 1 and a network where another electronic apparatus (or external server) is located, through short-range wireless area network (WAN). The wireless area networks may be wireless personal area networks. The other electronic apparatus may be a wearable device capable of mutually exchanging data with (or linking with) the electronic apparatus 1.

The location information module 525, which is a module for obtaining a location (or current location) of the electronic apparatus 1, may include a global positioning system (GPS) module or a Wi-Fi module.

The input unit 530 may include an image input unit such as the camera 531 for inputting an image signal, an audio input unit such as a microphone 532 for inputting an audio signal, and an input device 533 for receiving information from a user. The camera 531 may process image frames, such as still images or moving images, obtained by an image sensor in a video call mode or shooting mode. The processed image frames may be displayed on the display panel 10 or stored in the memory 570. The microphone 532 may process external audio signals into electrical sound data. The processed sound data may be variously used according to a function being performed (or application being run) in the electronic apparatus 1.

The main processor 510 may control an operation of the electronic apparatus 1 to correspond to information received via the input device 533. The input device 533 may include a mechanical input means, such as a button positioned on the rear surface or side surface of the electronic apparatus 1, a dome switch, a jog wheel, or a jog switch, or a touch input means. The touch input means may include a touch screen layer of the display panel 10.

The sensor unit 540 may include one or more sensors configured to sense at least one of information within the electronic apparatus 1, surrounding environment information of the electronic apparatus 1, or user information, and generate a sensing signal corresponding thereto. Based on this sensing signal, the main processor 510 may control driving or operation of the electronic apparatus 1 or perform data processing, functions, or operations associated with applications installed in the electronic apparatus 1. The sensor unit 540 may be a proximity sensor, an illumination sensor, or a facial recognition sensor as described above with respect to the component 40. The sensor unit 540 may include an acceleration sensor, a magnetic sensor, a G-sensor, a gyroscope sensor, a motion sensor, an RGB sensor, an infrared (IR) sensor, a finger scan sensor, an ultrasonic sensor, an optical sensor, and/or a battery gauge. In addition, the sensor unit 540 may include an environmental sensor or a chemical sensor. The environmental sensors may include, for example, a barometer, a hygrometer, a thermometer, a radiation detection sensor, a heat detection sensor, and/or a gas detection sensor. Chemical sensors may include, for example, an electronic nose, a healthcare sensor, and/or a biometric recognition sensor.

The output unit 550 may generate an output associated with vision, hearing, and tactile sensations, and may include at least one of the display panel 10, an audio output unit 551, a haptic module 552, or an optical output unit 553.

The display panel 10 may be configured to display (output) information processed in the electronic apparatus 1. For example, the display panel 10 may be configured to display execution screen information of an application driven in the electronic apparatus 1, or to display user interface (UI) or graphic user interface (GUI) information according to the execution screen information. The display panel 10 may include a display layer for displaying images and a touch screen layer for detecting a touch input of a user. Therefore, the display panel 10 may function as one of the input devices 533 that provide an input interface between the electronic apparatus 1 and the user, and at the same time, may function as the output units 550 that provide an output interface between the electronic apparatus 1 and the user.

The audio output unit 551 may output audio data received from the wireless communication unit 520 or stored in the memory 570 in a call signal reception mode, a call mode, recording mode, a speech recognition mode, a broadcast reception mode, or the like. The audio output unit 551 may output audio signals associated with functions performed in the electronic apparatus 1, such as call signal reception sound, message reception sound, or the like. The audio output unit 551 may include a receiver or a speaker. At least one of the receiver or the speaker may be a sound generation device that is attached below the display panel 10 and vibrate the display panel 10 to output sound. The sound generation device may be a piezoelectric element, or piezoelectric actuator, that contracts and expands in response to an electric signal, or an exciter that generates a magnetic force by using a voice coil and vibrates the display panel 10.

The haptic module 552 may generate various tactile effects that may be felt by the user. The haptic module 552 may provide vibration to the user as a tactile effect. The haptic module 552 may not only transfer a tactile effect through direct contact, but also may be implemented such that the user may feel the tactile effect through muscle sensations in the fingers or arms.

The optical output unit 553 may output a signal for notifying the user of the occurrence of an event by using light from a light source. Examples of events occurring in the electronic apparatus 1 may include receiving a message, receiving a call signal, receiving a missed call, an alarm, a schedule alarm, a schedule reminder, receiving an e-mail, receiving information through an application, and the like. The signal output from the optical output unit 553 may be implemented as the electronic apparatus 1 emits light of a single color or a plurality of colors from the front or rear thereof. The outputting of the signal may be terminated when the electronic apparatus 1 detects the user's identification of the event.

The interface unit 560 serves as a passageway for various types of external devices connected to the electronic apparatus 1. The interface unit 560 may include at least one of a wired/wireless headset port, an external charger port, a wired/wireless data port, a memory card port, a port connecting a device equipped with an identification module, an audio input/output (I/O) port, a video I/O port, or an earphone port. When the electronic apparatus 1 is connected to an external device through the interface unit 560, the electronic apparatus 1 may perform an appropriate control associated with the connected external device.

The memory 570 may store data supporting various functions of the electronic apparatus 1. The memory 570 may store a plurality of application programs running on the electronic apparatus 1, data for an operation of the electronic apparatus 1, and instructions. At least some of the plurality of applications may be downloaded from an external server through wireless communication. The memory 570 may store an application for an operation of the main processor 510, or may temporarily store input/output data, e.g., data such as a phonebook, messages, still images, and moving images. In addition, the memory 570 may store haptic data for vibration of various patterns provided to the haptic module 552, and audio data associated with various sounds provided to the audio output unit 551.

The memory 570 may include a storage medium of at least one type from among a flash memory type, a hard disk type, a solid state disk type (SSD) type, a silicon disk drive (SDD) type, a multimedia card micro type, a card-type memory (e.g., secure digital (SD) or extreme digital (XD) memory), random access memory (RAM), static RAM (SRAM), read-only memory (ROM), electrically erasable programmable ROM (EEPROM), programmable ROM (PROM), magnetic memory, a magnetic disk, or an optical disk.

Under the control of the main processor 510, the power supply unit 580 may receive external power and/or internal power and supply power to each of elements included in the electronic apparatus 1. The power supply unit 580 may include the battery 80. In addition, the power supply unit 580 may have a connection port, and the connection port may be configured as an example of the interface unit 560 to which an external charger supplying power for battery charging is electrically connected. Alternatively, the power supply unit 580 may be configured to charge the battery 80 in a wireless manner. The battery 80 may be disposed not to overlap the main circuit board 50 in the third direction (z-axis direction). The battery 80 may overlap the battery hole BH of the bracket 60.

The lower cover 90 may define the exterior outline of the electronic apparatus 1, and may have an opening that exposes a part of the display panel 10. The lower cover 90 may be assembled with the display panel 10 such that the display area of the display panel 10 is exposed through the opening of the lower cover 90. The lower cover 90 may be positioned such that the display panel 10 is interposed between the lower cover 90 and the cover window 70. The lower cover 90 may be disposed below the main circuit board 50 and the battery 80. The lower cover 90 may be fastened and fixed to the bracket 60. The lower cover 90 may form the exterior shape of a lower portion of the electronic apparatus 1. The lower cover 90 may include plastic, metal, or both plastic and metal.

A second camera hole CMH2 through which a lower surface of the camera 531 is exposed may be formed in the lower cover 90. A location of the camera 531 and positions of the first and second camera holes CMH1 and CMH2 corresponding to the camera 531 are not limited to the embodiments shown in FIGS. 1 and 2, and may be variously modified.

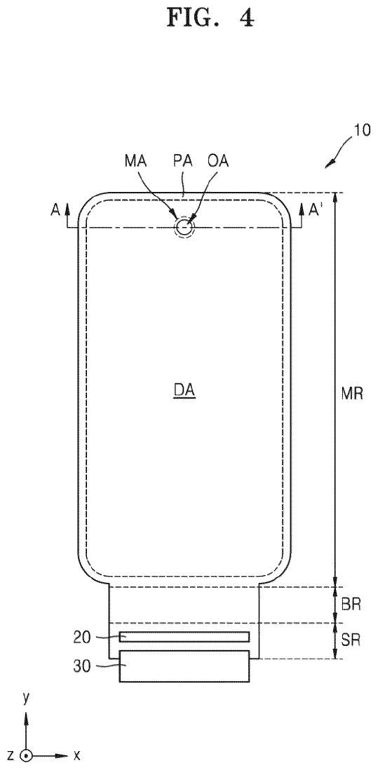

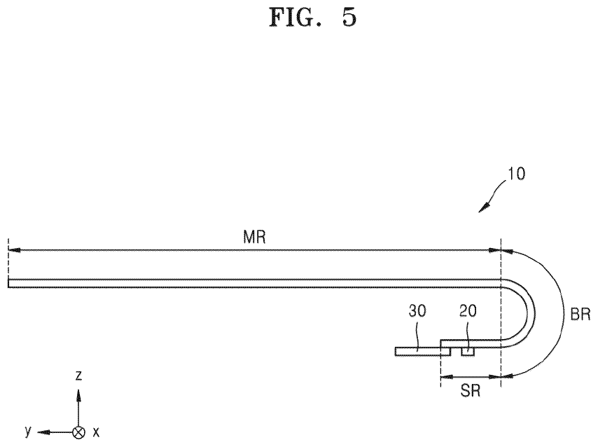

FIG. 4 is a plan view schematically illustrating the display panel 10 according to an embodiment, and FIG. 5 is a side view schematically illustrating the display panel 10 of FIG. 4. The electronic apparatus 1 described above may include the display panel 10 shown in FIGS. 4 and 5.

The display panel 10 may include the display area DA and a peripheral area PA outside the display area DA. The display area DA is a portion in which an image is displayed, and a plurality of pixels may be disposed in the display area DA. The display area DA may have any one of various shapes such as a circle, an ellipse, a polygon, and/or a specific shape. FIG. 4 shows that the display area DA has an approximately rectangular shape with round edges.

The peripheral area PA may be disposed outside the display area DA. A width in the first direction (x-axis direction) of a portion of the peripheral area PA located at the bottom of the display area DA and extending in the first direction (x-axis direction) may be smaller than a width of the display area DA in the first direction (x-axis direction). This structure may make it easy for at least a part of the peripheral area PA to be bent.

A planar shape of the display panel 10 shown in FIG. 4 may be substantially identical to a shape of the substrate 100 included in the display panel 10. When it is described that the display panel 10 includes the display area DA and the peripheral area PA outside the display area DA, it may indicate that the substrate 100 includes the display area DA and the peripheral area PA outside the display area DA. Hereinbelow, for convenience of descriptions, it is described that the substrate 100 includes the display area DA and the peripheral area PA.

The display panel 10 may include a main area MR, a bending area BR outside the main area MR, and a sub-area SR spaced apart from the main area MR with the bending area BR therebetween. The main area MR may be disposed at one side of the bending area BR, and the sub-area SR may be disposed on the other side of the bending area BR. The display panel 10 may be bent in the bending area BR, as shown in FIG. 5, and when viewed from the third direction (e.g., a z-axis direction), at least part of the sub-area SR may overlap the main area MR. FIG. 5 shows the display panel 10 in a bent state. For example, the display panel 10 may be a foldable display panel and the display area DA of the display panel 10 may be bent about a bending axis extending across the display area DA. In an embodiment, the display panel 10 may not be bent. The sub-area SR may be a non-display area.

The data driver 20 may be disposed in the sub-area SR of the display panel 10. The data driver 20 may be disposed on the display panel 10 in the form of an IC. For example, the data driver 20 may be a data driving IC configured to generate data signals.

The display circuit board 30 may be affixed to an end of the sub-area SR of the display panel 10. The display circuit board 30 may be electrically connected to the data driver 20 or the like through a pad of the sub-area SR of the display panel 10.

As described above with reference to FIG. 2, the display panel 10 may have the opening area OA located within the display area DA. And the display panel 10 may have the intermediate area MA located between the display area DA and the opening area OA.

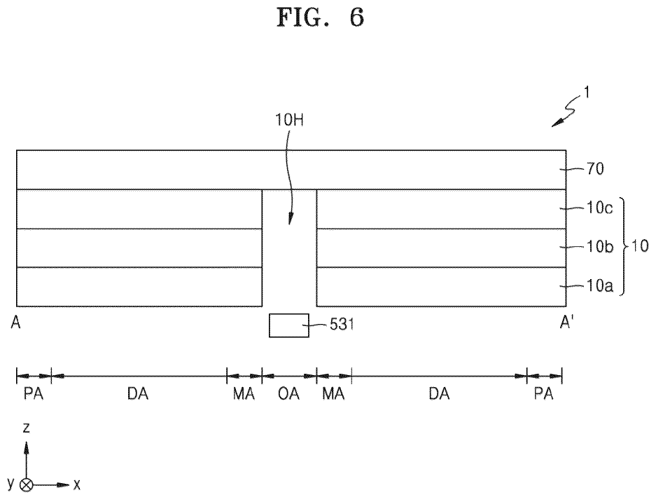

FIG. 6 is a cross-sectional view schematically illustrating a cross-section of the display panel 10 taken along line A-A′ of FIG. 4. FIG. 6 shows not only the display panel 10 but also the cover window 70 and the camera 531 together, for convenience of illustrations. As described above, the electronic apparatus 1 may include the display panel 10 and the camera 531 located in the opening area OA of the display panel 10.

The display panel 10 may include an image generation layer 10a, an input detection layer 10b, and an optical function layer 10c.

The image generation layer 10a may include display elements (or light-emitting elements) that emit light to display an image. The display element may include a light-emitting diode, such as an organic light-emitting diode including an organic emission layer. In an embodiment, the display element may be an inorganic light-emitting diode including inorganic materials. The inorganic light-emitting diode may include a PN diode including inorganic semiconductor-based materials. When a voltage is applied in a forward direction to a PN junction diode, holes and electrons may be injected, and energy generated by recombination of the holes and electrons may be converted into light energy so that light of a certain color is emitted. The aforementioned light-emitting diodes may have a width of several to several hundred micrometers, or several to several hundred nanometers.

Of course, embodiments are not limited thereto. For example, the image generation layer 10a may include a quantum dot layer. In this case, light that is generated from the light-emitting layer included in the image generation layer 10a and has a wavelength belonging to a predetermined wavelength band may be converted into light having a preset wavelength by the quantum dot layer.

The input detection layer 10b may obtain coordinate information according to an external input, such as a touch event. The input detection layer 10b may include sensing electrodes and/or touch electrodes and signal lines (e.g., trace lines) electrically connected to the sensing electrodes and/or touch electrodes. The input detection layer 10b may detect an external input through a mutual capacitance sensing method and/or a self-capacitance sensing method.

The input detection layer 10b may be disposed on the image generation layer 10a. The input detection layer 10b may be directly formed on the image generation layer 10a, or may be formed separately and then attached to the image generation layer 10a through an adhesive layer such as an optically transparent adhesive. In the former case, the input detection layer 10b may be formed continuously after the process of forming the image generating layer 10a, and in this case, the adhesive layer may not be interposed between the input detection layer 10b and the image generating layer 10a. FIG. 6 illustrates that the input detection layer 10b is interposed between the image generation layer 10a and the optical function layer 10c, however, various modifications may be made to the structure. For example, the input detection layer 10b may be disposed on the optical function layer 10c.

The optical function layer 10c may include an anti-reflection layer. The anti-reflection layer may reduce the reflectivity of light (external light) traveling from the outside toward the display panel 10 through the cover window 70. The antireflection layer may include a phase retardation film and a polarization film. Alternatively, the anti-reflection layer may include a black matrix and color filters. In the latter case, the color filters may be arranged in consideration of the color of light emitted from the image generation layer 10a.

To improve the transmittance of the opening area OA, the display panel 10 may include a hole 10H, which may be a through hole extending through the entire thickness of the display panel 10. The hole 10H may extend through the image generation layer 10a, the input detection layer 10b, and the optical function layer 10c.

The cover window 70 may be disposed over the display panel 10. The cover window 70 may be attached to the optical function layer 10c through an adhesive layer such as a transparent optical clear adhesive (OCA). The cover window 70 may cover the hole 10H included in the display panel 10.

The opening area OA may be an area where the hole 10H of the display panel 10 is located. An electronic element, such as the camera 531 or the component 40, may be placed in the opening area OA (in the −z direction of the display panel 10). For example, the electronic element may overlap the opening area OA in the plan view. FIG. 6 shows that the camera 531 is positioned to correspond to the opening area OA as described above. In an embodiment, at least a portion of the camera 531 may be positioned in the hole 10H of the display panel 10.

FIG. 7 is a cross-sectional view schematically illustrating a cross-section taken along a line perpendicular to line A-A′ of the display panel 10 of FIG. 4.

Referring to FIG. 7, the display panel 10 may include a display layer 200 and a thin film encapsulation layer 300 disposed on a substrate 100. The image generation layer 10a described above with reference to FIG. 6 may include the substrate 100, the display layer 200, and the thin film encapsulation layer 300.

The substrate 100 may include glass, ceramic, metal, or polymer resin. The substrate 100 may include a polymer resin, such as, for example, polyethersulfone, polyacrylate, polyetherimide, polyethylene naphthalate, polyethylene terephthalate, polyphenylene sulfide, polyarylate, polyimide, polycarbonate, or cellulose acetate propionate. The substrate 100 may have a multilayer structure including two layers containing such polymer resin and an inorganic layer interposed between the two layers. For example, as shown in an enlarged view portion of FIG. 7, the substrate 100 may include a first base layer 100a, an inorganic layer 100b, and a second base layer 100c. Alternatively, the substrate 100 may have a structure in which the base layer and the inorganic layer are alternately stacked. The inorganic layer 100b may include silicon nitride, silicon oxide and/or silicon oxynitride, and may have a single-layer structure or a multi-layer structure. The inorganic layer 100b may act as a barrier layer that prevents the penetration of impurities and/or external foreign substances.

The display layer 200 may have a plurality of pixels. The display layer 200 may include a display element layer 200A including a display element arranged for each pixel, and a pixel circuit layer 200B including a pixel circuit arranged for each pixel and insulating layers. The pixel circuit may include a thin film transistor and a storage capacitor, and the display element may include an organic light-emitting diode (OLED).

The thin film encapsulation layer 300 may cover the display layer 200. The thin film encapsulation layer 300 may include at least one inorganic encapsulation layer and at least one organic encapsulation layer. The thin film encapsulation layer 300 may prevent or minimize the penetration of impurities such as moisture from the outside into the display element.

As described above, the display panel 10 may include the hole 10H penetrating the display panel 10. The holes 10H may correspond to the opening area OA. FIG. 7 shows that the substrate 100 has a through hole 100H, the display layer 200 has a through hole 200H, and the thin film encapsulation layer 300 has a through hole 300H, thereby forming the hole 10H extending through the display panel 10.

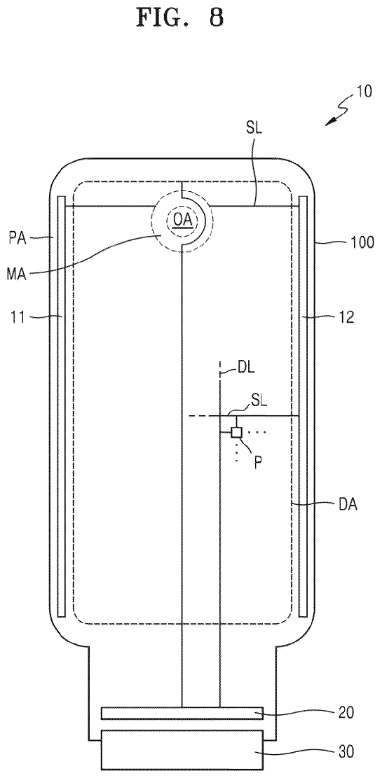

FIG. 8 is a plan view schematically illustrating the display panel 10 included in the electronic apparatus of FIG. 1. As shown in FIG. 8 and as described above, the display panel 10 may include the opening area OA, the intermediate area MA (also referred to as the first area) around the opening area OA, the display area DA (also referred to as the second area) around the intermediate area MA, and a peripheral area PA around the display area DA. For example, the substrate 100 of the display panel 10 includes the through hole corresponding to the opening area OA, the display area DA outside the through hole to surround the through hole, the intermediate area MA between the through hole and the display area DA, and the peripheral area PA outside the display area DA.

The display panel 10 may include a plurality of pixels P in a display area DA, and the display panel 10 may display an image using light emitted from the pixels P. Each of the plurality of pixels P may emit red, green, or blue light using a display element such as a light-emitting diode. The plurality of pixels P may be electrically connected to scan lines SL and data lines DL.

In the peripheral area PA, scan drivers 11 and 12 that provide scan signals to each of pixels P, data drivers 20 that provide data signals to each of pixels P, a first power line (i.e., the driving voltage line) for providing the driving voltage to each of pixels P, and a second power line for providing a common voltage (i.e., second power voltage) to each of pixels P may be arranged.

The intermediate area MA may be immediately adjacent to and surround the opening area OA. The intermediate area MA may not have display elements such as light-emitting diodes that emit light. In an embodiment, a display element may also be located in the intermediate area MA, and in this case, a pixel circuit electrically connected to the display element may be located within the intermediate area MA or within the display area DA. Some of the signal lines that provide signals to pixels P located relatively adjacent to the opening area OA among the pixels P within the display area DA may pass through the intermediate area MA.

For example, the data line DL may cross the display area DA, but a portion of the data line DL may bypass the hole 10H of the display panel 10 formed in the opening area OA, through the intermediate area MA along the edge of the hole 10H. FIG. 8 shows that data lines DL cross the display area DA along the y-axis direction, but some data lines DL detour to partially surround the opening area OA in the intermediate area MA.

Some of scan lines SL may include a first portion and a second portion that extend across the display area DA along the x-axis and are separated from each other by the opening area OA. In this case, the first portion of the scan line SL located on one side (in −x direction) of the opening area OA may be electrically connected to the scan driver 11 located on one side (in-x direction) of the opening area OA, and the second portion of the scan line SL located on the other side (in +x direction) of the opening area OA may be electrically connected to the scan driver 12 located on the other side (in +x direction) of the opening area OA. Accordingly, scan lines SL may not need to bypass the opening area OA to partially surround the opening area OA through intermediate area MA. If the display panel 10 has only one scan driver, some scan lines SL may bypass the opening area OA to partially surround the opening area OA in the intermediate area MA.

For reference, FIG. 8 shows that the data driver 20 disposed on the substrate 100 so as to be adjacent to one edge of the substrate 100 (in-y direction), embodiments are not limited thereto. For example, the data driver 20 may be disposed on a printed circuit board that is electrically connected to the display panel 10 through pads located at one edge of the display panel 10. If the data driver 20 is disposed on the substrate 100 so as to be adjacent to one edge of the substrate 100 (in-y direction) as shown in FIG. 8, a portion of the substrate 100 may be bent as described above with reference to FIG. 5 so that the portion of the substrate 100 where the data driver 20, etc., is located may overlap the display area DA and may be positioned behind the display area DA.

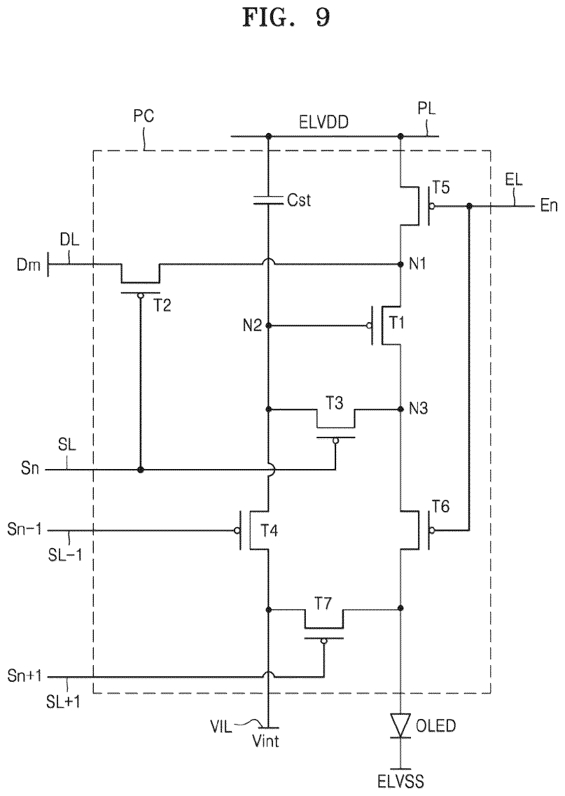

FIG. 9 is an equivalent circuit diagram of the pixel circuit PC electrically connected to the display element such as the organic light-emitting diode OLED included in the display panel 10 of FIG. 8.

As shown in FIG. 9, the pixel circuit PC including a plurality of thin film transistors and a capacitor may be electrically connected to the display element such as the organic light emitting diode OLED. FIG. 9 shows that the pixel circuit PC includes seven thin film transistors T1 through T7 and a storage capacitor Cst. However, embodiments may not be limited thereto, and the number of the thin film transistors and the capacitor and connection relationship therebetween may be variously changed.

The plurality of thin film transistors T1 through T7 and the storage capacitor Cst may be connected to signal lines SL, SL−1, SL+1, EL, and DL, an initialization voltage line VIL and/or a driving voltage line PL. At least one of these lines, for example, the driving voltage line PL, may be shared by neighboring pixels P.

The plurality of thin-film transistors T1 through T7 may include a driving transistor T1, a switching transistor T2, a compensation transistor T3, a first initialization transistor T4, an operation control transistor T5, an emission control transistor T6, and a second initialization transistor T7.

The light-emitting diode LED, such as an OLED, may include a pixel electrode and an opposite electrode, the pixel electrode of the light-emitting diode LED may receive supply of a driving current by being connected to the driving transistor T1 via the emission control transistor T6, and the opposite electrode may receive a supply of a second power voltage ELVSS. The light-emitting diode LED may generate light having a luminance corresponding to the driving current.

FIG. 9 shows that all of the thin film transistors T1 through T7 are P-channel MOSFETs (PMOSs), but embodiments are not limited thereto. For example, all of the plurality of thin-film transistors T1 through T7 may be N-channel MOSFETs (NMOSs). Alternatively, some of the plurality of thin-film transistors T1 through T7 may be PMOSs, whereas the others may be NMOSs. The plurality of thin-film transistors T1 through T7 may include amorphous silicon or polysilicon. Alternatively, at least some of the thin-film transistors T1 through T7 may include an oxide semiconductor.

The signal lines may include a scan line SL that transmits a scan signal Sn to the switching transistor T2 and the compensation transistor T3, a previous scan line SL−1 that transmits a previous scan signal Sn−1 to the first initialization transistor T4, a next scan line SL+1 that transmits a next scan signal Sn+1 to the second initialization transistor T7, an emission control line EL that transmits an emission control signal En to the operation control transistor T5 and the emission control transistor T6, and a data line DL that crosses the scan line SL and transmits a data signal Dm.

The driving voltage line PL may transmit a driving voltage ELVDD to the driving transistor T1, and the initialization voltage line VIL may transmit an initialization voltage Vint that initializes the driving transistor T1 and initializes the pixel electrode of the light-emitting diode LED.

A driving gate electrode of the driving transistor T1 may be connected to a first capacitor electrode of the storage capacitor Cst, one of a source region and a drain region of the driving transistor T1 may be connected to the driving voltage line PL via the operation control transistor T5, and the other of the source region and the drain region of the driving transistor T1 may be electrically connected to the pixel electrode of the light-emitting diode LED via the emission control transistor T6. The driving transistor T1 may supply the driving current to the light-emitting diode LED by receiving the data signal Dm in response to a switching operation of the switching transistor T2. In an embodiment, the driving transistor T1 may control an amount of current flowing through the light-emitting diode LED in response to a voltage changed by the data signal Dm.

A switching gate electrode of the switching transistor T2 may be connected to the scan line SL that transmits the scan signal Sn, one of a source region and a drain region of the switching transistor T2 may be connected to the data line DL, and the other of the source region and the drain region of the switching transistor T2 may be connected to a first node N1. The first node N1 is connected to the source/drain of the driving transistor T1 and also to the driving voltage line PL via the operation control transistor T5. The switching transistor T2 may transmit the data signal Dm from the data line DL to the driving transistor T1, in response to a voltage applied to the scan line SL. For example, the switching transistor T2 may be turned on in response to the scan signal Sn received through the scan line SL and may perform a switching operation of transmitting the data signal Dm, which is transmitted through the data line DL, to the driving transistor T1.

A compensation gate electrode of the compensation transistor T3 is connected to the scan line SL. One of a source region and a drain region of the compensation transistor T3 may be connected to a third node N3, which is also connected to a source/drain of the driving transistor T1 and the pixel electrode of the light-emitting diode LED via the emission control transistor T6. The other of the source region and the drain region of the compensation transistor T3 may be connected to a second node N2, which is connected to the first capacitor electrode of the storage capacitor Cst and the driving gate electrode of the driving transistor T1. The compensation transistor T3 may be turned on in response to the scan signal Sn received through the scan line SL and may cause the driving transistor T1 to be diode-connected thereto.

A first initialization gate electrode of the first initialization transistor T4 may be connected to the previous scan line SL−1. One of a source region and a drain region of the first initialization transistor T4 may be connected to the initialization voltage line VIL. The other of the source region and the drain region of the first initialization transistor T4 may be connected to a lower electrode of the storage capacitor Cst and the driving gate electrode of the driving transistor T1. For example, the first initialization transistor T4 may be turned on in response to the previous scan signal Sn−1 received through the previous scan line SL−1 and may perform an initialization operation of initializing a voltage of the driving gate electrode of the driving transistor T1 by transmitting the initialization voltage Vint to the second node N2 and the driving gate electrode of the driving transistor T1.

An operation control gate electrode of the operation control transistor T5 may be connected to the emission control line EL, one of a source region and a drain region of the operation control transistor T5 may be connected to the driving voltage line PL, and the other may be connected to the driving transistor T1 and the switching transistor T2.

An emission control gate electrode of the emission control transistor T6 may be connected to the emission control line EL, one of a source region and a drain region of the emission control transistor T6 may be connected to the third node N3, the driving transistor T1 and the compensation transistor T3, and the other of the source region and the drain region of the emission control transistor T6 may be electrically connected to the pixel electrode of the light-emitting diode LED.

The operation control transistor T5 and the emission control transistor T6 are simultaneously turned on in response to the emission control signal En received through the emission control line EL and cause the driving voltage ELVDD to be transmitted to the light-emitting diode LED through the driving transistor T1, such that the driving current flows through the light-emitting diode LED.

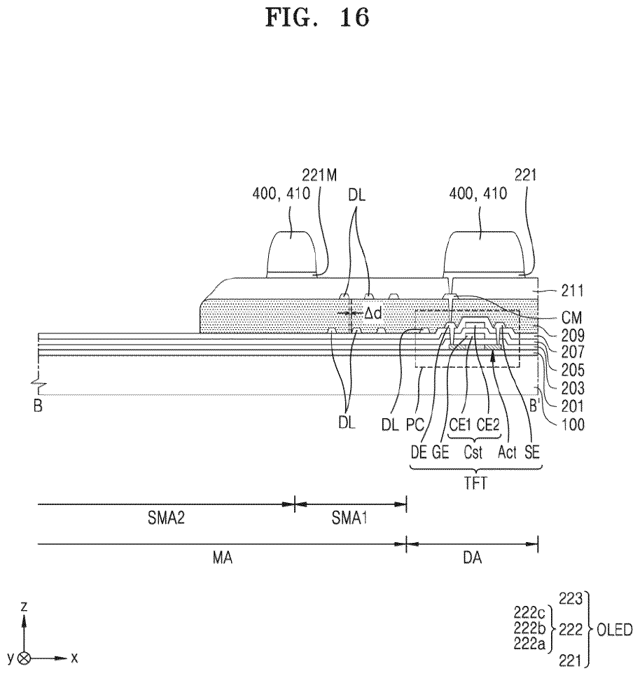

A second initialization gate electrode of the second initialization transistor T7 may be connected to the next scan line SL+1, one of a source region and a drain region of the second initialization transistor T7 may be connected to the pixel electrode of the light-emitting diode LED, and the other of the source region and the drain region of the second initialization transistor T7 may be connected to the initialization voltage line VIL to receive supply of the initialization voltage Vint. The second initialization transistor T7 is turned on in response to the next scan signal Sn+1 received through the next scan line SL+1 and initializes the pixel electrode of the light-emitting diode LED. For reference, the next scan line SL+1 may be a scan line SL of a pixel that is adjacent to the pixel P shown in FIG. 16 and electrically connected to the data line DL. For example, the scan line SL may transmit the same electrical signal with a time difference and function as a scan line SL of one pixel or function as a next scan line SL+1 of an adjacent pixel.

The storage capacitor Cst may include the first capacitor electrode and a second capacitor electrode. The first capacitor electrode of the storage capacitor Cst is connected to the driving gate electrode of the driving transistor T1, and the second capacitor electrode of the storage capacitor Cst is connected to the driving voltage line PL. The storage capacitor Cst may store an electric charge corresponding to a difference between the voltage of the driving gate electrode of the driving transistor T1 and the driving voltage ELVDD.

Detailed operations of each pixel P according to an embodiment are as follows.

During an initialization period, when the previous scan signal Sn−1 is supplied through the previous scan line SL−1, the first initialization transistor T4 is turned on, and the driving transistor T1 is initialized by the initialization voltage Vint supplied from the initialization voltage line VIL.

During a data programming period, when the scan signal Sn is supplied through the scan line SL, the switching transistor T2 and the compensation transistor T3 are turned on. In this case, the driving transistor T1 is diode-connected by the compensation transistor T3 that is turned on, and biased in a forward direction. Then, a compensation voltage (Dm+Vth, Vth has a negative value) that is obtained by subtracting a threshold voltage (Vth) of the driving transistor T1 from the data signal Dm supplied from the data line DL is applied to the driving gate electrode of the driving transistor T1. The driving voltage ELVDD and the compensation voltage (Dm+Vth) are applied to opposite ends of the storage capacitor Cst, and the storage capacitor Cst stores an electric charge corresponding to a difference between voltages at opposite ends thereof.

During an emission period, the operation control transistor T5 and the emission control transistor T6 are turned on in response to the emission control signal En supplied from the emission control line EL. The driving current is generated according to the difference between the voltage of the driving gate electrode of the driving transistor T1 and the driving voltage ELVDD, and the driving current is supplied to the light-emitting diode LED through the emission control transistor T6.

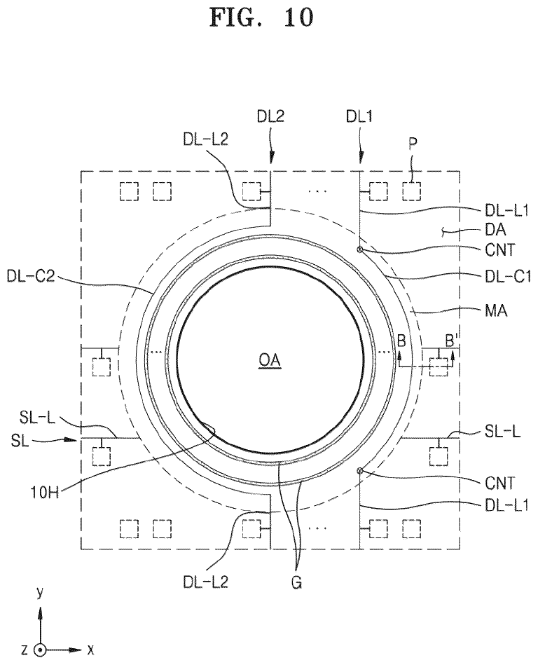

FIG. 10 is a plan view schematically illustrating a portion of the display panel 10 of FIG. 8. Particularly, FIG. 10 is a plan view schematically illustrating the opening area OA, the intermediate area MA, and a portion of the display area DA of the display panel 10 of FIG. 8. As shown in FIG. 10, pixels P are arranged in the display area DA.

The intermediate area MA, which may be referred to as the first area, may be located between the opening area OA and the display area DA, which may be referred to as the second area. In a plan view, pixels P adjacent to the opening area OA may be spaced apart from each other with respect to the opening area OA. For example, the pixels P may be spaced apart in the vertical direction (y-axis direction) with respect to the opening area OA, or may be spaced apart from each other in the left and right directions (x-axis direction) with respect to the opening area OA.

Among signal lines that supply signals to pixel circuits connected to light-emitting diodes of respective pixels P, signal lines adjacent to the opening area OA may bypass the opening area OA and/or the hole 10H. Some of data lines DL passing through the display area DA are positioned in the same column, extend (in the y-axis direction) to provide data signals to pixels P positioned on one side (in a +y direction) of the opening area OA and pixels P positioned on the other side (in the −y direction) of the opening area OA, and may bypass the opening area OA and/or the hole 10H along edges of the opening area OA and/or hole 10H in the intermediate area MA.

FIG. 10 shows that a first data line DL1 includes a first extension portion DL-L1 electrically connected to the pixels P positioned on one side (in the +y direction) of the opening area OA, a first extension portion DL-L1 electrically connected to the pixels P positioned on the other side (in the −y direction) of the opening area OA, and a first bypass portion DL-C1 bypassing the opening area OA and/or the hole 10H along the edges of the opening area OA and/or the hole 10H in the intermediate area MA. The first bypass portion DL-C1 may electrically connect the two first extension portions DL-L1 spaced apart from each other. As shown in FIG. 1, the first bypass portion DL-C1 may be substantially positioned on one side (in a +x direction) of the opening area OA. The first bypass portion DL-C1 may be positioned on a different layer from a layer on which the first extension portions DL-L1 are positioned, in which case, as shown in FIG. 10, the first bypass portion DL-C1 may be connected to the first extension portions DL-L1 through contact holes CNT. In another embodiment, the first bypass portion DL-C1 and the first extension portions DL-L1 may also be integrally formed.

FIG. 10 shows that a second data line DL2 includes a second extension portion DL-L2 electrically connected to the pixels P positioned on one side (in the +y direction) of the opening area OA, a second extension portion DL-L2 electrically connected to the pixels P positioned on the other side (in the −y direction) of the opening area OA, and a second bypass portion DL-C2 bypassing the opening area OA and/or the hole 10H along the edges of the opening area OA and/or the hole 10H in the intermediate area MA. The second bypass portion DL-C2 may electrically connect the two second extension portions DL-L2 spaced apart from each other. As shown in FIG. 10, the second bypass portion DL-C2 may be substantially positioned on one side (in the −x direction) of the opening area OA. As shown in FIG. 10, the second bypass portion DL-C2 and the second extension portions DL-L2 may be integrally formed as a single body. Unlike this, in one embodiment, the second bypass portion DL-C2 may be positioned on a different layer from a layer on which the second extension portions DL-L2 are positioned, in which case the second bypass portion DL-C2 may be connected to the second extension portions DL-L2 through contact holes (not shown).

The scan line SL may be separated or disconnected with respect to the opening area OA. FIG. 10 shows that the scan line SL includes two sub-scan lines SL-L separated by the opening area OA. A sub-scan line SL-L arranged on the left side (in a −x direction) of the opening area OA may receive a signal from the scan driver 11 (see FIG. 8) arranged on the left side (in the −x direction) of the display area DA, and a sub-scan line SL-L arranged on the right side (in the +x direction) of the opening area OA may receive a signal from the scan driver 12 (see FIG. 8) arranged on the right side (in the +x direction) of the display area DA. Of course, in one embodiment, these sub-scan lines SL-L may be electrically connected to each other by a bypass portion in the intermediate area MA, and the display panel 10 may include one scan driver.

Grooves G may be positioned in the intermediate area MA. The grooves G may be between the opening area OA and an area where the data lines DL bypass. For example, the grooves G may be between the first bypass portion DL-C1 and the opening area OA and between the second bypass portion DL-C2 and the opening area OA. In the plan view viewed from a direction substantially perpendicular to the substrate 100 (z-axis direction), each of the grooves G may have a closed loop shape surrounding the opening area OA. The grooves G may be spaced apart from each other. In one embodiment, each of the grooves G is spaced apart from the outer edge of the opening area OA by a constant distance.

FIG. 11 is a cross-sectional view schematically illustrating a cross-section of the display panel 10 of FIG. 10 taken along line B-B′.

A buffer layer 201 may be disposed over the substrate 100. The buffer layer 201 may prevent impurities from penetrating into a semiconductor layer Act of the thin film transistor TFT. The buffer layer 201 may include an inorganic insulating material such as silicon nitride, silicon oxynitride, and/or silicon oxide, and may have a single-layer structure or a multi-layer structure.

The pixel circuit PC may be disposed on the buffer layer 201. The pixel circuit PC may include the thin film transistor TFT and the storage capacitor Cst. The thin film transistor TFT may include the semiconductor layer Act, a gate electrode GE, a source electrode SE, and/or a drain electrode DE. The thin film transistor TFT shown in FIG. 11 may be the driving transistor T1. In the pixel circuit PC described above with reference to FIG. 9, the emission control transistor T6 is interposed between the driving transistor T1 and the organic light-emitting diode OLED. In such a case, unlike the structure shown in FIG. 11, the thin film transistor TFT, which is the driving transistor T1, would not be connected to the pixel electrode 221 of the organic light-emitting diode through the contact metal layer CM, but would be electrically connected to the emission control transistor, which is not shown in FIG. 11. The emission control transistor may be electrically connected to the pixel electrode 221 of the organic light-emitting diode. For convenience of descriptions, a structure in which the thin film transistor TFT of FIG. 11 is connected to the pixel electrode 221 of the organic light-emitting diode through the contact metal layer CM is described.

The data line DL of the pixel circuit PC may be electrically connected to the switching transistor included in the pixel circuit PC.

The semiconductor layer Act may include polysilicon. Alternatively, the semiconductor layer Act may include amorphous silicon, an oxide semiconductor material, an organic semiconductor material, etc. The gate electrode GE may include a low-resistance metal material. For example, the gate electrode GE may include a conductive material including molybdenum (Mo), aluminum (AI), copper (Cu), and/or titanium (Ti), and may have a multi-layer structure or a single-layer structure. For example, the gate electrode GE may have a three-layer structure of a molybdenum layer, an aluminum layer, and a molybdenum layer (Mo/Al/Mo).

The gate insulating layer 203 between the semiconductor layer Act and the gate electrode GE may include an inorganic insulating material such as silicon oxide, silicon nitride, silicon oxynitride, aluminum oxide, titanium oxide, tantalum oxide, and/or hafnium oxide. The gate insulating layer 203 may have a single-layer structure or a multi-layer structure.

The source electrode SE and the drain electrode DE may be disposed on the same layer as the data line DL and may include the same material as the data line DL. The source electrode SE, the drain electrode DE, and the data line DL may include a material with high conductivity. The source electrode SE and the drain electrode DE may include a conductive material including molybdenum (Mo), aluminum (AI), copper (Cu), titanium (Ti), etc., and may have a multi-layer structure or a single-layer structure. For example, the source electrode SE, the drain electrode DE, and the data line DL may have a multi-layer structure of a titanium layer, an aluminum layer, and a titanium layer (Ti/Al/Ti).

FIG. 11 shows that the thin film transistor TFT includes both the source electrode SE and the drain electrode DE, but embodiments are not limited thereto. For example, the drain region of the semiconductor layer Act of the thin film transistor TFT may be integrally formed with a source region of a semiconductor layer of another thin film transistor, and in this case, the thin film transistor TFT may not have the drain electrode DE and the other thin film transistor may not have a source electrode. In this case, the circuit diagram may show the drain of a thin film transistor TFT as being connected to the source of the other thin film transistor. In the pixel circuit PC shown in FIG. 9, the drain of the driving transistor T1 and the source of the emission control transistor T6 are shown to be connected at the third node N3. In this case, the driving transistor T1 may not have the drain electrode and the emission control transistor T6 may not have the source electrode, and the drain region of the semiconductor layer of the driving transistor T1 and the source region of the emission control transistor T6 may be integrally formed as a single body. Similarly, in the pixel circuit PC shown in FIG. 9, because the source of the driving transistor T1 is connected to the drain of the operation control transistor T5, the driving transistor T1 may not have the source electrode and the operation control transistor T5 may not have the drain electrode, and the source region of the semiconductor layer of the driving transistor T1 and the drain region of the operation control transistor T5 may be integrally formed as a single body. Accordingly, the driving transistor T1 may not have the source electrode and the drain electrode.

The storage capacitor Cst may include a lower electrode CE1 and an upper electrode CE2 that overlap each other with a first interlayer insulating layer 205 therebetween. The storage capacitor Cst may overlap the thin film transistor TFT. FIG. 11 shows that the gate electrode GE of the thin film transistor TFT is the lower electrode CE1 of the storage capacitor Cst. Of course, embodiments are not limited thereto, and the storage capacitor Cst may not overlap the thin film transistor TFT. A second interlayer insulating layer 207 may cover the storage capacitor Cst. The upper electrode CE2 of the storage capacitor Cst may include a conductive material including molybdenum (Mo), aluminum (AI), copper (Cu), and/or titanium (Ti), and may have a multi-layer structure or a single-layer structure.

The first interlayer insulating layer 205 and the second interlayer insulating layer 207 may include an inorganic insulating material such as silicon oxide, silicon nitride, silicon oxynitride, aluminum oxide, titanium oxide, tantalum oxide, and/or hafnium oxide. The first interlayer insulating layer 205 and the second interlayer insulating layer 207 may have a single-layer structure or a multi-layer structure.

A first organic insulating layer 209 may cover the pixel circuit PC including the thin film transistor TFT and the storage capacitor Cst.

The pixel circuit PC may be electrically connected to the pixel electrode 221. For example, as shown in FIG. 11, the contact metal layer CM may be interposed between the thin film transistor TFT and the pixel electrode 221. The contact metal layer CM may be connected to the thin film transistor TFT through a contact hole defined in the first organic insulating layer 209, and the pixel electrode 221 may be connected to the contact metal layer CM through a contact hole defined in the second organic insulating layer 211 disposed on the first organic insulating layer 209 to cover the contact metal layer CM. The contact metal layer CM may include a conductive material including molybdenum (Mo), aluminum (AI), copper (Cu), and/or titanium (Ti), and may have a multi-layer structure or a single-layer structure. For example, the contact metal layer CM may have a multi-layer structure of a titanium layer, an aluminum layer, and a titanium layer (Ti/Al/Ti).

The first organic insulating layer 209 and the second organic insulating layer 211 may include an organic insulating material such as acrylic, polystyrene (PS), polymethylmethacrylate (PMMA), BCB (Benzocyclobutene), polyimide, or HMDSO (Hexamethyldisiloxane). For example, the first organic insulating layer 209 and the second organic insulating layer 211 may include polyimide. The first organic insulating layer 209 and/or the second organic insulating layer 211 may have a substantially flat upper surface.

The pixel electrode 221 disposed on the second organic insulating layer 211 may be a (semi) transparent electrode or a reflective electrode. For example, the pixel electrode 221 may include a reflective layer including Ag, Mg, Al, Pt, Pd, Au, Ni, Nd, Ir, Cr or a compound thereof, and a transparent or semitransparent electrode layer disposed on the reflective layer. The transparent or semitransparent electrode layer may include at least one selected from the group consisting of indium tin oxide (ITO), indium zinc oxide (IZO), zinc oxide (ZnOₓ:ZnO or ZnO₂), indium oxide (In₂O₃), indium gallium oxide (IGO), and aluminum zinc oxide (AZO). For example, the pixel electrode 221 may have a three-layer structure of ITO/Ag/ITO. The pixel electrode 221 may appear to have an isolated shape in the plan view.

A pixel-defining layer 215 may be disposed over the second organic insulating layer 211. The pixel-defining layer 215 may prevent arcs and the like from occurring at the edge of the pixel electrode 221 by covering the edge of the pixel electrode 221 and increasing the distance between the pixel electrode 221 and the common electrode 223 above the pixel electrode 221. For example, the pixel-defining layer 215 has an opening to expose the central portion of the pixel electrode 221. The pixel-defining layer 215 may be formed by a method such as spin coating and may include one or more organic insulating materials selected from the group consisting of polyimide, polyamide, acrylic resin, benzocyclobutene, and phenol resin. Alternatively, the pixel-defining layer 215 may include an inorganic insulating material such as silicon nitride (SiNx), silicon oxynitride (SiON), or silicon oxide (SiOx).

An intermediate layer 222 interposed between the pixel electrode 221 and the common electrode 223 may include an emission layer 222b. The intermediate layer 222 may include a first functional layer 222a between the emission layer 222b and the pixel electrode 221, or may include a second functional layer 222c between the emission layer 222b and the common electrode 223. The emission layer 222b may emit light of a predetermined color and may include a polymer or low-molecular organic material.

The first functional layer 222a may have a single-layer structure or a multi-layer structure. For example, when the first functional layer 222a includes a polymer material, the first functional layer 222a may have a single-layer structure including a hole transport layer (HTL) and may include polyethylene dihydroxythiophene (PEDOT: poly-(3,4)-ethylene-dihydroxy thiophene) or polyaniline (PANI: polyaniline). When the first functional layer 222a includes a low-molecular-weight material, the first functional layer 222a may include a hole injection layer (HIL) and the hole transport layer (HTL).

The second functional layer 222c may include an electron transport layer (ETL) and/or an electron injection layer (EIL).

Meanwhile, unlike the structure shown in FIG. 11, the intermediate layer 222 may include a first stack including an emission layer 222b and a functional layer, a second stack including an emission layer 222b and a functional layer, and a charge generation layer between the first stack and the second stack. The charge generation layer may include a negative charge generation layer and a positive charge generation layer. The emission efficiency of a tandem light-emitting diode LED having a plurality of emission layers may be further increased by the negative charge generation layer and the positive charge generation layer.

The negative charge generation layer may be an n-type charge generation layer. The negative charge generation layer may supply electrons. The negative charge generation layer may include a host and a dopant. The host may include an organic material. The dopant may include a metal material. The positive charge generation layer may be a p-type charge generation layer. The positive charge generation layer may supply holes. The positive charge generation layer may include a host and a dopant. The host may include an organic material. The dopant may include a metal material.

The emission layer 222b may have a patterned shape corresponding to the pixel electrode 221. Layers included in the intermediate layer 222 other than the emission layer 222b may be formed in various ways. For example, a layer included in the intermediate layer 222 other than the emission layer 222b may be integrally formed as a single body throughout the plurality of pixel electrodes 221. Layers included in the intermediate layer 222 other than the emission layer 222b may also be located in the intermediate area MA.

The common electrode 223 may be a light-transmitting electrode or a reflective electrode. For example, the common electrode 223 may be a transparent or semitransparent electrode and may include a metal film with a small work function including Li, Ca, Al, Ag, Mg or a compound thereof (e.g., LiF). In one embodiment, the common electrode 223 may further include a TCO (transparent conductive oxide) film such as ITO, IZO, ZnO, ZnO₂ or In₂O₃ disposed on the metal thin film.

The common electrode 223 may be formed continuously over the entire display area DA to cover the display area DA, and may be disposed over the intermediate layer 222 and the pixel-defining layer 215. For example, each of the pixel electrodes 221 may be arranged to correspond to each light-emitting diode LED, and the common electrode 223 may be integrally formed as a single body to correspond to the plurality of organic light-emitting diodes OLEDs. The plurality of organic light-emitting diodes OLEDs may share the common electrode 223, and a laminated structure of the pixel electrode 221, the intermediate layer 222, and the common electrode 223 may correspond to the organic light-emitting diode OLED.

The capping layer 230 may be disposed over the common electrode 223. For example, the capping layer 230 may include LiF. In an embodiment, the capping layer 230 may be omitted.

A spacer 217 may be disposed on the pixel-defining layer 215. The spacer 217 may include an organic insulator such as polyimide. Alternatively, the spacer 217 may include an inorganic insulator, or may include an organic insulator and an inorganic insulator.

The spacer 217 may include a material different from the material of the pixel-defining layer 215 or may include the same material as the pixel-defining layer 215. For example, the pixel-defining layer 215 and the spacer 217 may include polyimide. When the pixel-defining layer 215 and the spacer 217 include the same material, the pixel-defining layer 215 and the spacer 217 may be formed simultaneously in one mask process using a halftone mask. Among the aforementioned intermediate layer 222a and/or 222c, the functional layers or the common electrodes 223 may cover the spacer 217.

A thin film encapsulation layer 300 may cover the organic light-emitting diode OLED. The thin film encapsulation layer 300 may include at least one organic encapsulation layer and at least one inorganic encapsulation layer, and FIG. 11 shows that the thin film encapsulation layer 300 includes a first inorganic encapsulation layer 310, a second inorganic encapsulation layer 330, and an organic encapsulation layer 320 interposed therebetween. In an embodiment, the number of organic and inorganic encapsulating layers and the stacking order may be changed.

Each of the first inorganic encapsulation layer 310 and the second inorganic encapsulation layer 330 may include one or more inorganic materials selected from aluminum oxide, titanium oxide, tantalum oxide, hafnium oxide, zinc oxide, silicon oxide, silicon nitride, and silicon oxynitride. Each of the first inorganic encapsulation layer 310 and the second inorganic encapsulation layer 330 may have a single-layer structure or a multi-layer structure. The organic encapsulation layer 320 may include a polymer material. The polymer material may include acrylic resins such as polymethyl methacrylate or polyacrylic acid, epoxy resins, polyimides, and/or polyethylene. For example, the organic encapsulation layer 320 may include acrylate.

The first inorganic encapsulation layer 310 and the second inorganic encapsulation layer 330 may include different materials. For example, the first inorganic encapsulation layer 310 may include silicon oxynitride, and the second inorganic encapsulation layer 330 may include silicon nitride.

The intermediate area MA shown in FIG. 11 may include a first sub-intermediate area SMA1 and a second sub-intermediate area SMA2. The first sub-intermediate area SMA1 may be farther from the opening area OA where the hole 10H of the display panel 10, i.e., the first hole H1 of the substrate 100, is than the second sub-intermediate area SMA2. In other words, the second sub-intermediate area SMA2 is closer to the opening area OA than the first sub-intermediate area SMA1. The lines and grooves G1, G2, and G that extend around the opening area OA may be arranged in the intermediate area MA.

Lines, such as data lines DL, may be arranged in the first sub-intermediate area SMA1. The data lines DL in the first sub-intermediate area SMA1 shown in FIG. 11 correspond to the bypass portions of the data lines DL described above with reference to FIG. 10, such as the first bypass portion DL-C1 and/or the second bypass portion DL-C2. The first sub-intermediate area SMA1 may be a line area or bypass area through which lines such as data lines DLs bypass.

In the first sub-intermediate area SMA1, data lines DL may be arranged alternately with an insulating layer between them. For example, one of the neighboring data lines DL may be disposed below the insulating layer (e.g., the first organic insulating layer, 209) and the other may be disposed on the insulating layer (e.g., the first organic insulating layer, 209). When data lines DL are arranged alternately with an insulating layer between them, the distance (Ad, pitch) between neighboring data lines in the plan view may be reduced. FIG. 11 shows data lines DL located in the first sub-intermediate area SMA1. However, In an embodiment, bypass portions of the scan lines SL may also be located in the first sub-intermediate area SMA1.

Structures to prevent or minimize the penetration of impurities such as moisture from the outside into the display area DA may be located in the second sub-intermediate area SMA2. In an embodiment, some of such structures may be located across the first sub-intermediate area SMA1 and the second sub-intermediate area SMA2.

The buffer layer 201, the gate insulating layer 203, the first interlayer insulating layer 205, and the second interlayer insulating layer 207 may include an inorganic insulating material as described above, and may be disposed on the substrate 100 in the display area DA and the intermediate area MA. In some embodiments, the buffer layer 201, the gate insulating layer 203, the first interlayer insulating layer 205, and the second interlayer insulating layer 207 may be disposed throughout the entire display area DA and the intermediate area MA. The first organic insulating layer 209 and the second organic insulating layer 211 disposed over the inorganic insulating layers including the inorganic insulating material may also be disposed on the substrate 100 throughout the display area DA and the intermediate area MA.

As described above, the intermediate area MA between the display area DA and the opening area OA may be referred to as the first area, and the display area DA may be referred to as the second area outside the first area. A mask conductive layer 221M may be located in the intermediate area MA. The mask conductive layer 221M may be disposed on the second organic insulating layer 211 and may include the same material as the pixel electrode 221. Therefore, during the manufacturing process, the mask conductive layer 221M and the pixel electrode 221 may be formed simultaneously using the same material. If necessary, in one embodiment, the mask conductive layer 221M may be omitted.

In the display area DA, the intermediate layer 222, the common electrode 223, the capping layer 230, and the thin film encapsulation layer 300 may be disposed over the pixel electrode 221. The intermediate layer 222, the common electrode 223, the capping layer 230, and the thin film encapsulation layer 300 may extend to the intermediate area MA and may also be disposed over the mask conductive layer 221M.

As shown in FIG. 11, an end of the second organic insulating layer 211 that is closest to the hole 10H may be disposed on the first organic insulating layer 209. To this end, as described below, the mask conductive layer 221M may prevent or minimize a material for forming the second organic insulating layer 211 from remaining outside the first organic insulating layer 209 during the manufacturing process.

FIG. 11 is a cross-sectional view schematically illustrating a cross-section taken along line B-B′ of the display panel 10 of FIG. 10, and thus shows a portion of the mask conductive layer 221M. As shown in FIG. 11, the mask conductive layer 221M may have an isolated shape. When viewed from the direction substantially perpendicular to the substrate 100 (z-axis direction), i.e. in the plan view, the mask conductive layer 221M may completely surround the hole 10H. For example, in the plan view, the mask conductive layer 221M may completely surround the opening area OA. The shape of the mask conductive layer 221M may be a ring shape such that the hole 10H is located inside the mask conductive layer 221M in the plan view. As shown in FIG. 11, the mask conductive layer 221M including an end of the mask conductive layer 221M that is closest to the hole 10H may be disposed on the second organic insulating layer 211. Depending on the embodiment, the mask conductive layer 221M may be entirely or partially disposed on the second organic insulating layer 211.

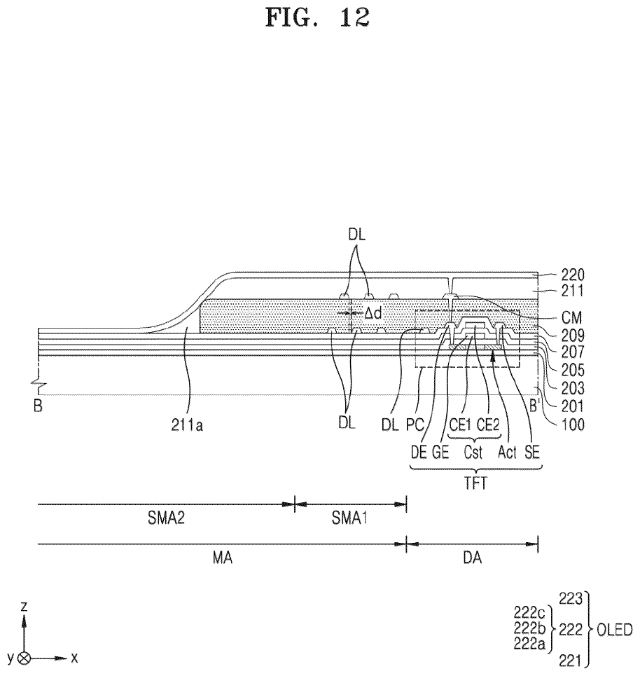

FIGS. 12 through 17 are cross-sectional views schematically illustrating manufacturing operations of a display panel according to one embodiment.

First, a material layer for forming the second organic insulating layer is formed on the first organic insulating layer 209 to cover the contact metal layer CM, etc., and the material layer for forming the second organic insulating layer is patterned to form the second organic insulating layer 211. In the process of forming the second organic insulating layer 211 on the first organic insulating layer 209, the material for forming the second organic insulating layer may remain outside the first organic insulating layer 209. FIG. 12 shows such a residual portion 211a. Particularly, FIG. 12 shows that the residual portion 211a exists adjacent to the end of the first organic insulating layer 209 in the region adjacent to the hole 10H (−x direction).

In order to prevent or minimize the penetration of impurities such as moisture from the outside into the display area DA through the hole 10H, a predetermined distance may be maintained between the hole 10H and an end of an organic layer that is close to the hole 10H. The distance reduces the penetration of impurities because the organic layer may function as a path for the impurities to enter the display area DA. The position of the end of the first organic insulating layer 209 in the area adjacent to the hole 10H (−x direction) may be selected to prevent or minimize the penetration of the impurities. In such a situation, the second organic insulating layer 211 is formed on the first organic insulating layer 209, but during the patterning process for forming the second organic insulating layer 211, the material for forming the second organic insulating layer may remain outside the first organic insulating layer 209. As shown in FIG. 12, if such a residual portion 211a is located outside the first organic insulating layer 209 so as to be adjacent to an edge of the first organic insulating layer 209, the impurities from the outside may penetrate into the display area DA through the residual portion 211a. Therefore, a process of removing the residual portion 211a is necessary. The process of removing the residual portion 211a is described below.

As shown in FIG. 12, a material layer 220 for forming the pixel electrode is formed using the material for a pixel electrode. When patterning the material layer for forming the second organic insulating layer to form the second organic insulating layer 211, a contact hole that extends through the second organic insulating layer 211 to at least a portion of the contact metal layer CM may be formed (or defined) at the same time. Accordingly, the material layer 220 for forming the pixel electrode may contact the contact metal layer CM through the contact hole. The material layer 220 for forming the pixel electrode may cover the second organic insulating layer 211, the residual portion 211a, and the second interlayer insulating layer 207 on the side that is close to the hole 10H.

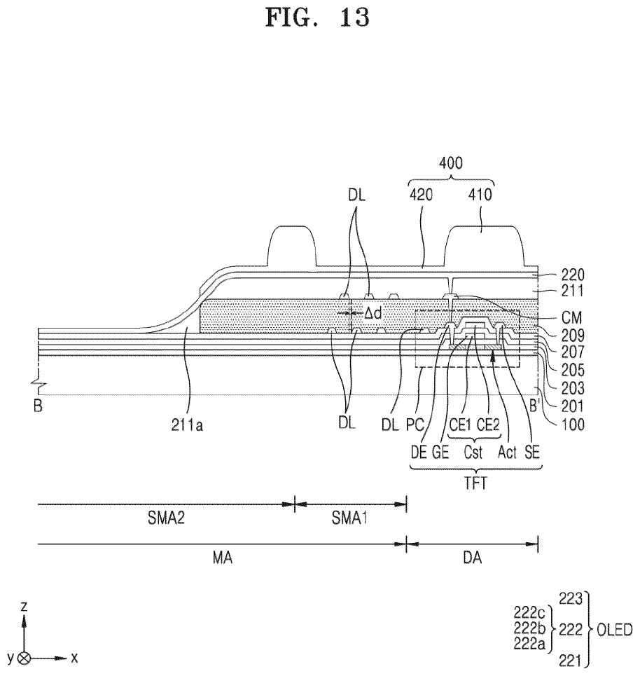

Then, a photoresist layer 400 may be formed on the material layer 220 for forming the pixel electrode, as shown in FIG. 13. For example, an initial photoresist layer with a constant thickness may be formed (not shown). Parts of this initial photoresist layer may be exposed to different amounts of light through a halftone mask or the like. Following the exposure, the initial photoresist layer may be developed such that the photoresist layer 400 having the shape as shown in FIG. 13 may be formed. Through this exposure and development process, a part of the material layer 220 outside the second organic insulating layer 211 may be exposed without being covered by the photoresist layer 400.

Through the exposure and development process using the halftone mask, etc. as described above, the photoresist layer 400 may include thick first portions 410 and thin second portions 420. The first portions 410 may be portions where the material layer 220 for forming the pixel electrode will remain after subsequent processing, and the second portions 420 may be portions where the material layer 220 for forming the pixel electrode will be removed during subsequent processing. In one embodiment, the mask conductive layer 221M may be omitted, and in such a case, unlike as shown in FIG. 13, the photoresist layer 400 may not include the thick first portion 410 in the intermediate area MA during the manufacturing process.

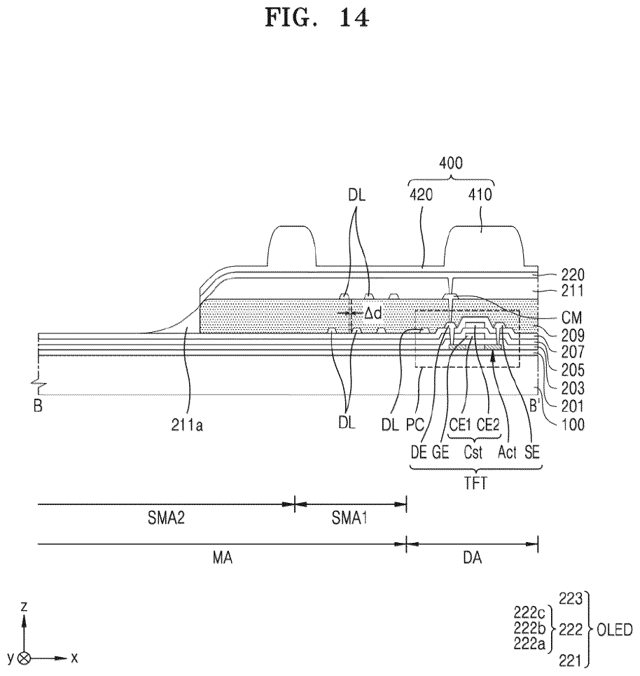

After forming the photoresist layer 400, the portion of the material layer 220 for forming the pixel electrode that is not covered by the photoresist layer 400 may be removed, as shown in FIG. 14. For this, a wet etching method using oxalic acid, etc., may be used. Accordingly, the residual portion 211a outside the first organic insulating layer 209 may be exposed to the outside without being covered by the material layer 220 for forming the pixel electrode.

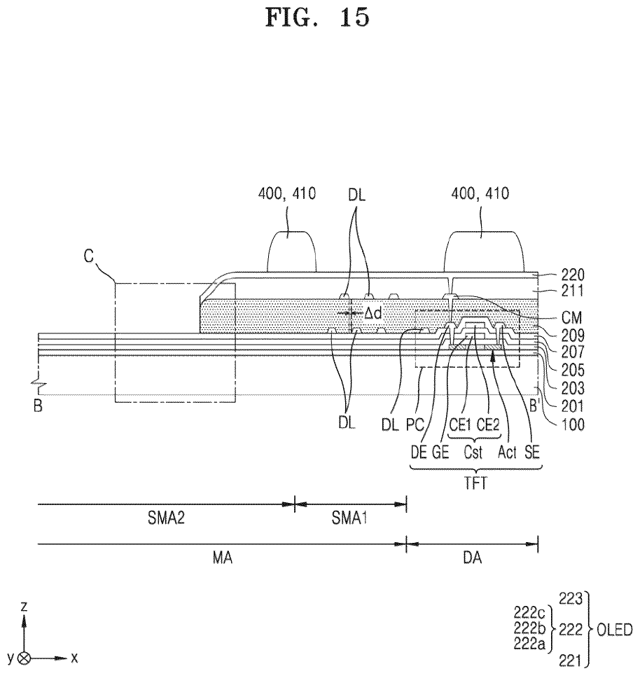

Without the cover of the material layer 220, the residual portion 211a outside the first organic insulating layer 209 may be removed through an ashing process, as shown in FIG. 15. The ashing may be performed in various ways, for example, oxygen plasma treatment may be used to remove the residual portion 211a. During the ashing process, a portion of the photoresist layer 400 may also be removed. Accordingly, the thin second portions 420 of the photoresist layer 400 are removed together with the residual portion 211a, and thickness of the thick first portions 410 of the photoresist layer 400 may be reduced. However, the first portions 410 of the photoresist layer 400 may still exist on the material layer 220 for forming the pixel electrode, as shown in FIG. 15. The first portions 410 within the display area DA may correspond to areas where the pixel electrodes 221 will be formed later, and the first portion 410 within the intermediate area MA may correspond to an area where the mask conductive layer 211M will be formed later. In one embodiment, the mask conductive layer 221M may be omitted. In such a case, unlike as shown in FIG. 13, the photoresist layer 400 may not include the thick first portion 410 in the intermediate area MA. In this case, unlike as shown in FIG. 15, the first portion 410 may not exist in the intermediate area MA.

The material layer 220 for forming the pixel electrode may protect the second organic insulating layer 211, etc. under the material layer 220 during the ashing process.

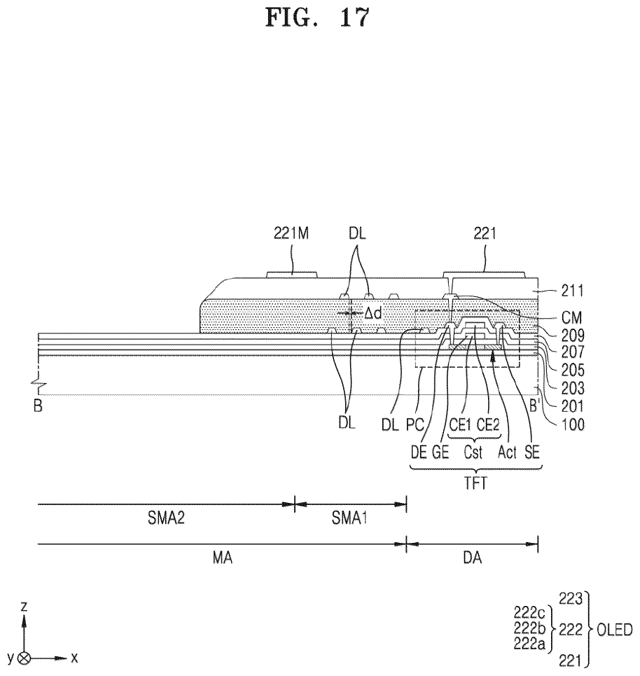

In a state as shown in FIG. 15, a portion of the material layer 220 that is not covered by the photoresist layer 400 may be removed. For this, a wet etching method using oxalic acid, etc., may be used. Through this process, the plurality of pixel electrodes 221 located in the display area DA and the mask conductive layer 221M located in the intermediate area MA may be formed, as shown in FIG. 16. If necessary, in one embodiment, the mask conductive layer 221M may be omitted. And then, as shown in FIG. 17, the photoresist layer 400 on the pixel electrodes 221 and the mask conductive layer 221M may be removed, and then a process of forming a pixel defining layer 215, etc., may be performed.

Through this process, it is possible to effectively prevent or minimize the residual portion 211a from remaining outside the first organic insulating layer 209 during the process of forming the second organic insulating layer 211 on the first organic insulating layer 209. The mask conductive layer 221M may be disposed on the second organic insulating layer 211 in the intermediate area MA to prevent the second organic insulating layer 211 from being damaged due to tolerance, etc. during the process described above. If this damage prevention function is desired, the mask conductive layer 221M would be formed to cover a larger area on the second organic insulating layer 211 than what is depicted in FIGS. 16 and 17. For example, in the cross-sectional views similar to FIGS. 16 and 17, the mask conductive layer 221M would extend a greater distance to the left and right than that shown in FIGS. 16 and 17.

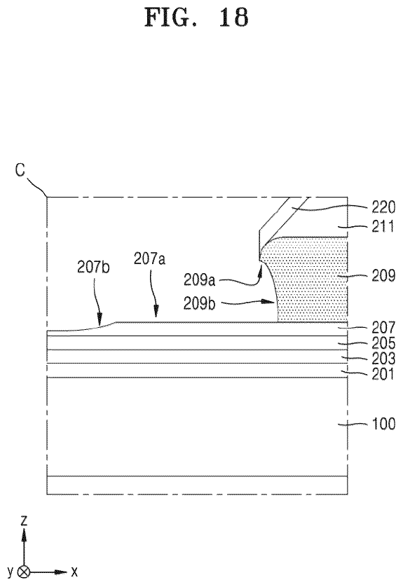

FIG. 18 is a cross-sectional view schematically illustrating a part of a display panel 10 according to one embodiment during the manufacturing process. For example, FIG. 18 may be an enlarged cross-sectional view of a portion C indicated by a broken line in FIG. 15. As shown in FIG. 18, the first organic insulating layer 209 may have an end portion adjacent to the hole 10H (−x direction) and the end portion may include an upper portion 209a and a lower portion 209b. The upper portion 209a may protrude farther than the lower portion 209b toward the hole 10H (−x direction).

As shown in FIG. 14, the residual portion 211a outside the first organic insulating layer 209 may be exposed without being covered by the material layer 220 for forming the pixel electrode. As mentioned above, the material layer 220 for forming the pixel electrode may prevent the first organic insulating layer 209 from being exposed. As depicted in FIG. 18, an upper surface of the end portion of the upper portion 209a of the first organic insulating layer 209 may be covered with the material layer 220 for forming the pixel electrode.

As described above in reference to FIG. 15, without the cover of the material layer 220, the residual portion 211a outside the first organic insulating layer 209 may be removed through an ashing process. During the ashing process, a portion of the photoresist layer 400 may also be removed. For example, the thin second portions 420 of the photoresist layer 400 are removed together with the residual portion 211a. Although the thickness of the thick first portions 410 of the photoresist layer 400 may be reduced, the thick first portions 410 of the photoresist layer 400 may still exist on the material layer 220, as shown in FIG. 15. In addition, during this process, a portion of a side surface of the first organic insulating layer 209 that is not covered by the material layer 220 for forming the pixel electrode may also be removed by ashing together with the residual portion 211a. Accordingly, more of the lower portion 209b of the side surface of the first organic insulating layer 209 facing the hole 10H (−x direction), that is farther away from the material layer 220 may be removed than the upper portion 209a that is adjacent to the material layer 220. As a result, as shown in FIG. 18, at the end portion of the first organic insulating layer 209 that is adjacent to the hole 10H (−x direction), the upper portion 209a may protrude beyond the lower portion 209b in the direction of the hole 10H (−x direction).

In the case of the second interlayer insulating layer 207, which is an inorganic insulating layer disposed under the first organic insulating layer 209, a portion of the second interlayer insulating layer 207 may be removed during the ashing process, although not to the same extent as a layer containing an organic material such as the residual portion 211a or the photoresist layer 400. Accordingly, while thickness of a first portion 207a of the second interlayer insulating layer 207, which would have been under the residual portion 211a, may be substantially maintained during the ashing process, thickness of a second portion 207b of the second interlayer insulating layer 207 that was outside the residual portion 211a may be reduced during the ashing process. Without the cover of the residual portion 211a, a portion near an upper surface of the second portion 207b is removed during the ashing process. As a result, the second portion 207b may be thinner than the first portion 207a.

The first portion 207a may be a portion of the second interlayer insulating layer 207 located between the first organic insulating layer 209 and the hole 10H, and the second portion 207b may be a portion of the second interlayer insulating layer 207 located between the first portion 207a and the hole 10H. FIG. 18 is the cross-sectional view schematically illustrating a portion of the display panel 10. Therefore, when viewed from the direction perpendicular to the substrate 100 (z-axis direction), i.e. in the plan view, the second portion 207b may have a ring shape that encircles or completely surrounds the hole 10H, and the first portion 207a may have a ring shape that encircles or completely surrounds the e second portion 207b that is between the hole 10H and the first portion 207a.

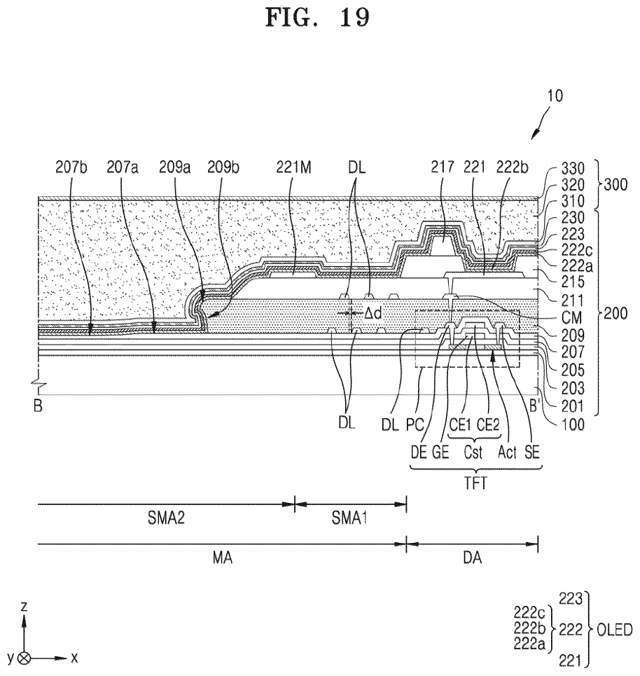

FIG. 19 is a cross-sectional view schematically illustrating a portion of a display panel 10 according to one embodiment. As shown in FIG. 18, FIG. 19 shows that the first organic insulating layer 209 may have an end portion adjacent to the hole 10H (−x direction) that includes the upper portion 209a and the lower portion 209b. The upper portion 209a may protrude beyond the lower portion 209b in the direction of the hole 10H (−x direction). Layers may be deposited on the upper portion 209a and the lower portion 209b of the edge of the organic insulating layer 209, and on the first portion 207a and the second portion 207b of the second interlayer insulating layer 207.

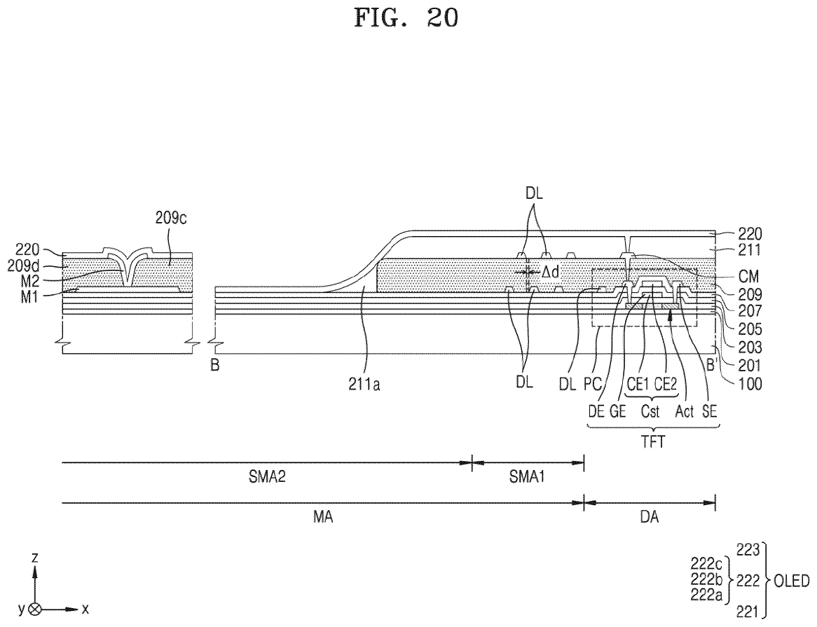

FIG. 20 through 23 are cross-sectional views schematically illustrating manufacturing operations of a display panel 10 according to one embodiment. The above description with reference to FIGS. 12 through 17 may also be applied to FIGS. 20 through 23.

The above description with reference to FIG. 12 may be applied to FIG. 20. As shown in FIG. 20, a first metal layer M1 may be disposed on the second interlayer insulating layer 207, which is an inorganic insulating layer, to be located in the second sub-intermediate area SMA2. The first metal layer M1 may be located closer to the hole 10H than the first organic insulating layer 209 and the residual portion 211a. The first metal layer M1 and elements disposed on the second interlayer insulating layer 207 in the display area DA may be formed simultaneously using the same material. For example, the first metal layer M1 and the source electrode SE and/or the drain electrode DE may be formed simultaneously using the same material.

As shown in FIG. 20, a first additional organic insulating layer 209c that is disconnected from the first organic insulating layer 209 may cover an edge of the first metal layer M1 that is closest to the first organic insulating layer 209. In addition, a second additional organic insulating layer 209d apart from the first additional organic insulating layer 209c may cover an edge of the first metal layer M1 that is closest to the hole 10H (−x direction). Although not explicitly depicted, the hole 10H is to the left of FIG. 20. The first additional organic insulating layer 209c, the second additional organic insulating layer 209d, and the first organic insulating layer 209 may be formed simultaneously using the same material.

A second metal layer M2 disposed on the first additional organic insulating layer 209c and the second additional organic insulating layer 209d may contact the first metal layer M1 through the space between the first additional organic insulating layer 209c and the second additional organic insulating layer 209d. Accordingly, the second metal layer M2 may have a shape in which the width of an upper portion is wider than the width of a lower portion. The second metal layer M2 and elements disposed on the first organic insulating layer 209 in the display area DA may be formed simultaneously using the same material. For example, the second metal layer M2 and the contact metal layer CM may be formed simultaneously using the same material.

When viewed from the direction perpendicular to the substrate 100 (z-axis direction), i.e. in plan view, each of the first metal layer M1, the first additional organic insulating layer 209c, the second additional organic insulating layer 209d, and the second metal layer M2 may have a ring shape that encircles or completely surrounds the hole 10H so that the hole 10H is located inside each of them. When viewed from the direction perpendicular to the substrate 100 (z-axis direction), i.e., in plan view, the gap between the first additional organic insulating layer 209c and the second additional organic insulating layer 209d may also have a ring shape that encircles or completely surrounds the hole 10H so that the hole 10H is located inside the gap. The material layer 220 for forming the pixel electrode may also cover the first additional organic insulating layer 209c, the second additional organic insulating layer 209d, and the second metal layer M2 during the manufacturing process.

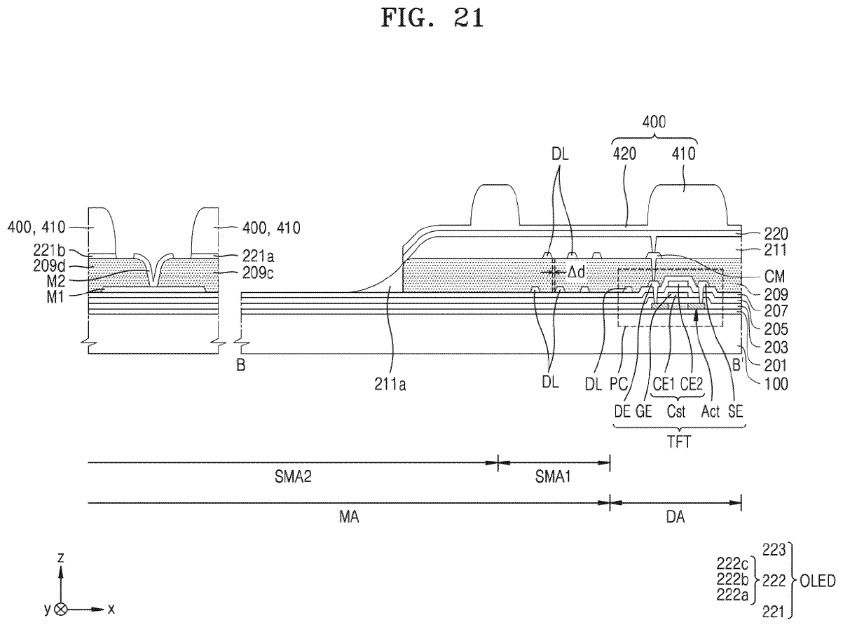

After forming the photoresist layer 400 on the material layer 220 for forming the pixel electrode as described above with reference to FIG. 13 and exposing and developing the photoresist layer 400, a portion of the material layer 220 for forming the pixel electrode exposed outside the photoresist layer 400 may be removed by a method such as wet etching. FIG. 21 illustrates that the material layer 220 for forming the pixel electrode is patterned in this manner. As shown in FIG. 21, through this process, the residual portion 211a is exposed to the outside of the material layer 220 for forming the pixel electrode, and at the same time, the first additional mask conductive layer 221a disposed on the first additional organic insulating layer 209c and the second additional mask conductive layer 221b disposed on the second additional organic insulating layer 209d are formed from the material layer 220. In this case, the first portion 410 of the photoresist layer 400 is disposed on each of the first additional mask conductive layer 221a and the second additional mask conductive layer 221b.

As described above, the contact metal layer CM may include a conductive material including molybdenum (Mo), aluminum (AI), copper (Cu), and/or titanium (Ti), and may have a multi-layer structure or a single-layer structure. For example, the contact metal layer CM may have a multi-layer structure of a titanium layer, an aluminum layer, and a titanium layer (Ti/Al/Ti). Also, as described above, the portions of the material layer 220 for forming the pixel electrode, which become the first additional mask conductive layer 221a and the second additional mask conductive layer 221b, may include at least one selected from the group including indium tin oxide (ITO), indium zinc oxide (IZO), zinc oxide (ZnOₓ:ZnO or ZnO₂), indium oxide (In₂O₃), indium gallium oxide (IGO), and aluminum zinc oxide (AZO). For example, the material layer 220 for forming the pixel electrode may have a three-layer structure of ITO/Ag/ITO.

Because the material layer 220 for forming the pixel electrode includes a different material from the contact metal layer CM, the first additional mask conductive layer 221a and the second additional mask conductive layer 221b may be formed using a wet etching method that uses an etchant (e.g., an etchant containing oxalic acid) that etches the material layer 220 for forming the pixel electrode at a relatively higher etching rate than the contact metal layer CM. As a result, the second metal layer M2 may be spaced apart from each of the first additional mask conductive layer 221a and the second additional mask conductive layer 221b and positioned between the first additional mask conductive layer 221a and the second additional mask conductive layer 221b. When viewed from the direction perpendicular to the substrate 100 (z-axis direction), i.e. in plan view, each of the first additional mask conductive layer 221a and the second additional mask conductive layer 221b may have a ring shape that encircles or completely surrounds the hole 10H.

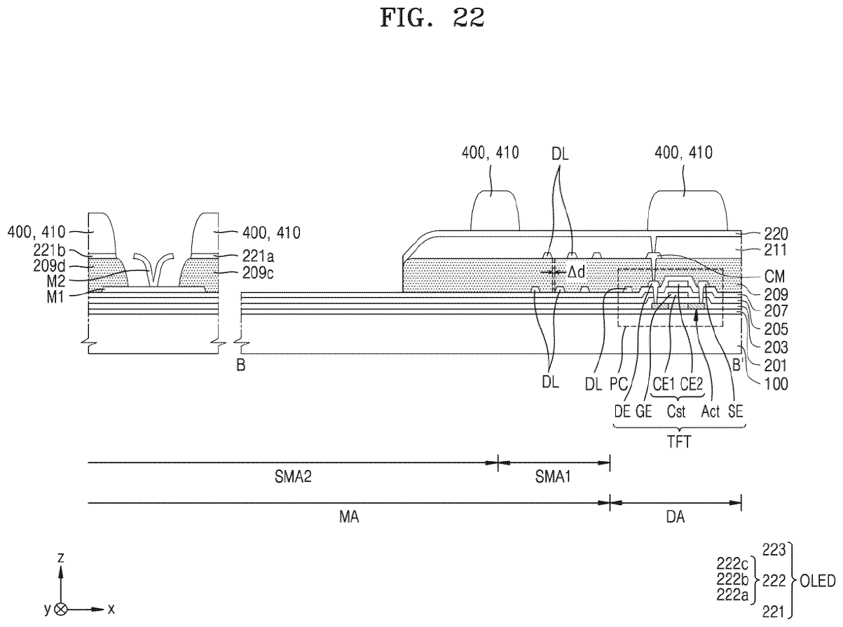

In the above embodiment, the residual portion 211a outside the first organic insulating layer 209 may be removed through an ashing process as described above, as shown in FIG. 22. The ashing process may also remove a part of the first additional organic insulating layer 209c between the second metal layer M2 and the first additional mask conductive layer 221a may be removed, and a part of the second additional organic insulating layer 209d between the second metal layer M2 and the second additional mask conductive layer 221b. Accordingly, as shown in FIG. 22, a second metal layer M2 having a curved V-shape may be disposed on the first metal layer M1 and spaced apart from the first additional organic insulating layer 209c and the second additional organic insulating layer 209d.

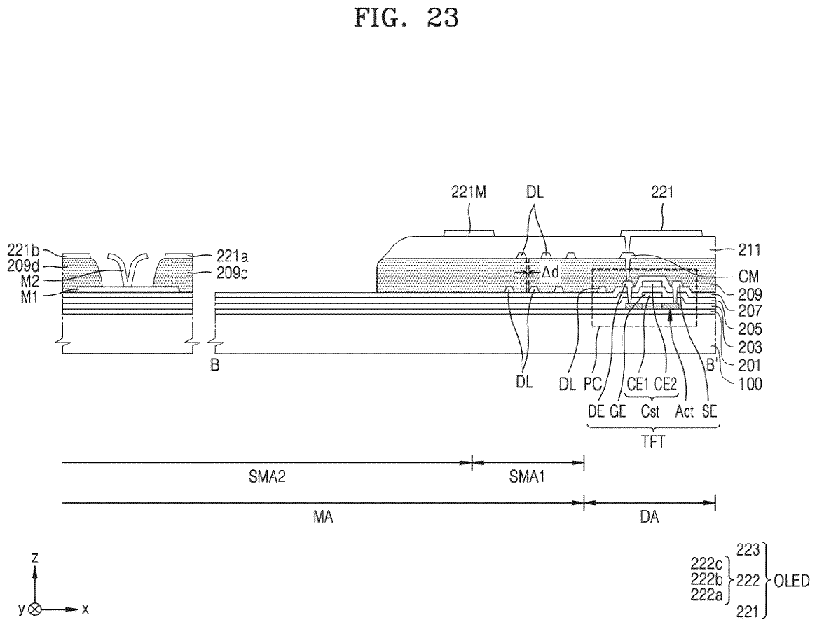

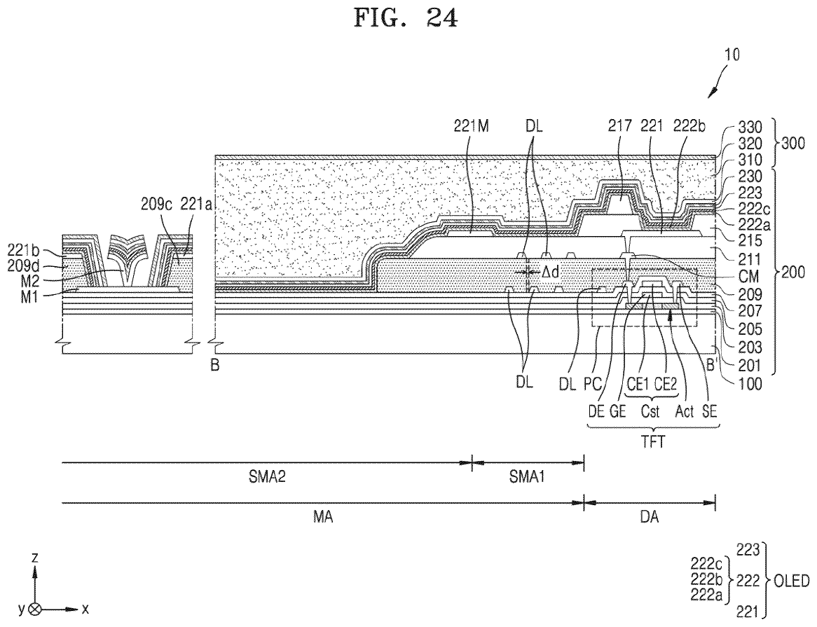

In the state shown in FIG. 22, a portion of the material layer 220 that is not covered by the photoresist layer 400 may be removed. For this, a wet etching method using oxalic acid, etc. may be used. Through this, the plurality of pixel electrodes 221 located within the display area DA and the mask conductive layer 211M located within the intermediate area MA may be formed. The photoresist layer 400 may be removed as shown in FIG. 23 in preparation for forming the pixel-defining layer 215, etc. to manufacture a display panel 10 shown in FIG. 24.

For reference, a dam formed simultaneously with the first organic insulating layer 209, the second organic insulating layer 211, and/or the pixel defining layer 215 using the same material may be positioned between the structures such as the first metal layer M1 and the second metal layer M2 shown in FIG. 24 and the first sub-intermediate area SMA1. The dam may have a ring shape encircling or completely surrounding the hole 10H in plan view. The area where the organic encapsulation layer 320 of the thin film encapsulation layer 300 is formed may be limited by the dam. The intermediate layer 222, the common electrode 223, the capping layer 230, the first inorganic encapsulating layer 310, and the second inorganic encapsulating layer 330 other than the organic encapsulating layer 320 may be formed not only in the display area DA but also in the intermediate area MA, and these layers may be disconnected in the space between the second metal layer M2 and the first additional mask conductive layer 221a, and in the space between the second metal layer M2 and the second additional mask conductive layer 221b. Accordingly, it is possible to effectively prevent or minimize impurities such as moisture from the outside from moving from the hole 10H to the display area DA through the interfaces between layers.

For reference, the space between the second metal layer M2 and the first additional mask conductive layer 221a and the space between the second metal layer M2 and the second additional mask conductive layer 221b are indicated as grooves G in FIG. 10. FIG. 24 shows that the display panel 10 includes the first metal layer M1, the second metal layer M2, the first additional mask conductive layer 221a, the second additional mask conductive layer 221b, the first additional organic insulating layer 209c, and the second additional organic insulating layer 209d. However, embodiments are not limited thereto. For example, the display panel 10 may include a plurality of such structures.

FIGS. 21 to 24 show that, when viewed from the direction substantially perpendicular to the substrate 100 (z-axis direction), i.e. in plan view, the end of the first additional mask conductive layer 221a that is closest to the second additional mask conductive layer 221b (−x direction) is disposed on the first metal layer M1, so that a portion of the first additional mask conductive layer 221a overlaps the first metal layer M1.

Similarly, FIGS. 21 to 24 show that, when viewed from the direction substantially perpendicular to the substrate 100 (z-axis direction), i.e. in plan view, an end of the second additional mask conductive layer 221b that is closest to the first additional mask conductive layer 221a (+x direction) is disposed on the first metal layer M1, so that a portion of the second additional mask conductive layer 221b overlaps the first metal layer M1. This way, the volume of a portion of the first additional organic insulating layer 209c to be removed and the volume of a portion of the second additional organic insulating layer 209d to be removed may be limited during the ashing process, so that the second metal layer M2 having a reverse taper shape may be apart from the first additional organic insulating layer 209c and the second additional organic insulating layer 209d and may be disposed on the first metal layer M1.

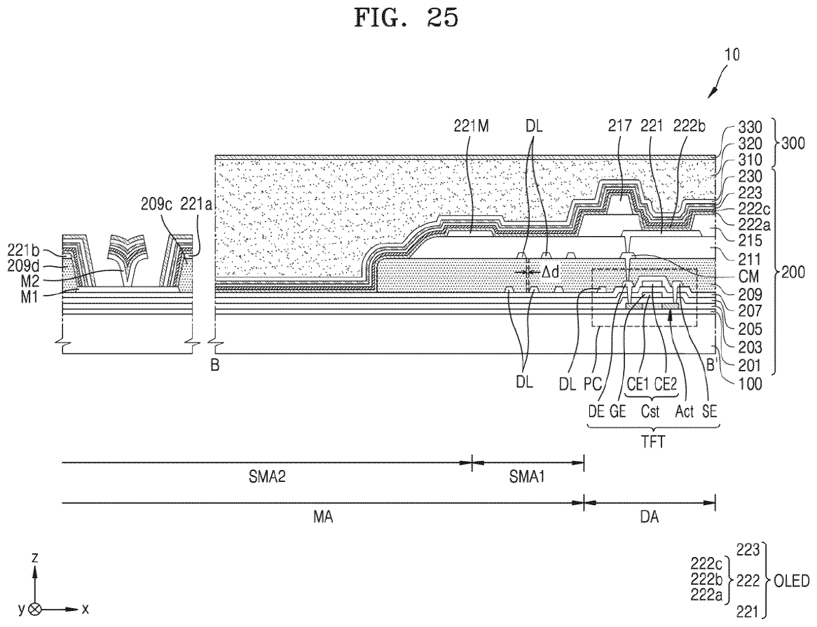

Embodiments are not limited thereto. As shown in FIG. 25, which is a cross-sectional view schematically illustrating a portion of a display panel 10 according to one embodiment, when viewed from the direction substantially perpendicular to the substrate 100 (z-axis direction), i.e. in plan view, the end of the first additional mask conductive layer 221a that is closest to the second additional mask conductive layer 221b (−x direction) may be aligned with (or coincide with) an end of the first metal layer M1. Similarly, when viewed from the direction substantially perpendicular to the substrate 100 (z-axis direction), i.e. in plan view, the end of the second additional mask conductive layer 221b that is closest to the first additional mask conductive layer 221a (+x direction) may be aligned with (or coincide with) an end of the first metal layer M1. Also in this case, the volume of a portion of the first additional organic insulating layer 209c to be removed and the volume of a portion of the second additional organic insulating layer 209d to be removed may be limited during the ashing process, so that the second metal layer M2 having a curved-V shape may be spaced apart from the first additional organic insulating layer 209c and the second additional organic insulating layer 209d and may be disposed on the first metal layer M1.

For comparison, consider a hypothetical case where, when viewed from the direction substantially perpendicular to the substrate 100 (z-axis direction), i.e. in plan view, the end of the first additional mask conductive layer 221a that is closest to the second additional mask conductive layer 221b (−x direction) is located beyond the end of the first metal layer M1, and the end of the second additional mask conductive layer 221b that is closest to the first additional mask conductive layer 221a (+x direction) is located beyond the end of the first metal layer M1. In this case, the volume of a portion of the first additional organic insulating layer 209c to be removed during the ashing process and the volume of a portion of the second additional organic insulating layer 209d to be removed during the ashing process increase significantly. In addition, in this hypothetical case, the first additional organic insulating layer 209c and the second additional organic insulating layer 209d may not be properly removed between the first additional mask conductive layer 221a and the first metal layer M1 or between the second additional mask conductive layer 221b and the first metal layer M1. If the first additional organic insulating layer 209c and the second additional organic insulating layer 209d are not properly removed, the second metal layer M2 may not be completely spaced apart from the first additional organic insulating layer 209c and the second additional organic insulating layer 209d. Therefore, it is desirable for the display panel 10 to have the structure where the first and second additional mask conductive layers 221a, 221b partially overlap the first metal layer M1 as described above with reference to FIG. 24 or FIG. 25.

So far, the structure of the display panel 10 has been mainly described, but embodiments are not limited thereto. An electronic apparatus 1 including such a display panel 10 may also be said to fall within the scope of the disclosure.

Although one or more embodiments have been described with reference to the embodiments shown in the drawings, these are merely exemplary, and those skilled in the art will understand that various modifications and equivalent other embodiments are possible therefrom. Therefore, the true technical protection scope should be determined by the technical idea of the appended claims.

According to one or more embodiments as described above, a display panel with a low defect rate and an electronic apparatus having the same can be implemented. However, the scope of the disclosure is not limited to or by this disclosure.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display panel comprising:
a substrate including a hole, a first area outside the hole, and a second area outside the first area;
a first organic insulating layer disposed on the substrate in the first area and the second area, an end portion of the first organic insulating layer that is closest to the hole including an upper portion and a lower portion, the upper portion extending beyond the lower portion toward the hole;
a second organic insulating layer disposed on the first organic insulating layer in the first area and the second area; and
a display element disposed on the second organic insulating layer in the second area, and including a pixel electrode disposed on the second organic insulating layer.

2. The display panel of claim 1, wherein an end of the second organic insulating layer that is closest to the hole is disposed on the first organic insulating layer.

3. The display panel of claim 1, further comprising a mask conductive layer disposed on the second organic insulating layer, located in the first area, and including a same material as the pixel electrode.

4. The display panel of claim 3, wherein the mask conductive layer is surrounded by different material.

5. The display panel of claim 3 wherein, in a view from a direction perpendicular to the substrate, the mask conductive layer surrounds the hole.

6. The display panel of claim 5 wherein, in a view from the direction perpendicular to the substrate, the mask conductive layer has a ring shape such that the hole is located inside of the mask conductive layer.

7. The display panel of claim 3, wherein an end of the mask conductive layer that is closest to the hole is disposed on the second organic insulating layer.

8. The display panel of claim 1, further comprising an inorganic insulating layer disposed on the substrate in the first area and the second area and interposed between the substrate and the first organic insulating layer,
wherein the inorganic insulating layer includes a first portion located between the first organic insulating layer and the hole and a second portion located between the first portion and the hole, and a thickness of the second portion is less than a thickness of the first portion.

9. The display panel of claim 1, further comprising:
a mask conductive layer disposed on the second organic insulating layer, located in the first area, and including a same material as the pixel electrode;
an inorganic insulating layer disposed on the substrate in the first area and the second area and interposed between the substrate and the first organic insulating layer;
a first metal layer disposed on the inorganic insulating layer and located between the hole and the end portion of the first organic insulating layer that is closest to the hole;
a first additional organic insulating layer covering an edge of the first metal layer that is closest to the first organic insulating layer and spaced apart from the first organic insulating layer;
a second additional organic insulating layer covering an edge of the first metal layer that is closest to the hole and spaced apart from the first additional organic insulating layer;
a first additional mask conductive layer disposed on the first additional organic insulating layer;
a second additional mask conductive layer disposed on the second additional organic insulating layer; and
a second metal layer disposed on the first metal layer, located between the first additional mask insulating layer and the second additional mask insulating layer, and spaced apart from the first additional mask insulating layer and the second additional mask insulating layer.

10. The display panel of claim 9, wherein a width of an upper portion of the second metal layer is greater than a width of a lower portion of the second metal layer.

11. The display panel of claim 9 wherein, in a view from a direction perpendicular to the substrate, a gap between the first additional organic insulating layer and the second additional organic insulating layer surrounds the hole.

12. The display panel of claim 9 wherein, in a view from a direction perpendicular to the substrate, each of the first metal layer and the second metal layer surrounds the hole.

13. The display panel of claim 9 wherein, in a view from a direction perpendicular to the substrate, an end of the first additional mask conductive layer that is closes to the second additional mask conductive layer is disposed on the first metal layer.

14. The display panel of claim 9 wherein, in a view from a direction perpendicular to the substrate, an end of the first additional mask conductive layer that is closest to the second additional mask conductive layer coincides with an end of the first metal layer that is closest to the first organic insulating layer.

15. The display panel of claim 9 wherein, in a view from a direction perpendicular to the substrate, an end of the second additional mask conductive layer that is closest to the first additional mask conductive layer is disposed on the first metal layer.

16. The display panel of claim 9 wherein, in a view from a direction perpendicular to the substrate, an end of the second additional mask conductive layer that is closest to the first additional mask conductive layer coincides with an end of the first metal layer that is closest to the hole.

17. The display panel of claim 9, wherein the first additional mask conductive layer and the second additional mask conductive layer each include a same material as the mask conductive layer.

18. The display panel of claim 9, wherein the first additional organic insulating layer and the second additional organic insulating layer each include a same material as the first organic insulating layer.

19. An electronic apparatus comprising:
a processor; and
a display panel configured to be controlled by the processor,
wherein the display panel includes:
a substrate comprising a hole, a first area outside the hole, and a second area outside the first area;
a first organic insulating layer disposed on the substrate in the first area and the second area, an end portion of the first organic insulating layer that is closest to the hole including an upper portion and a lower portion, the upper portion extending beyond the lower portion toward the hole;
a second organic insulating layer disposed on the first organic insulating layer in the first area and the second area; and
a display element disposed on the second organic insulating layer in the second area, and including a pixel electrode disposed on the second organic insulating layer.

20. The electronic apparatus of claim 19, further comprising an inorganic insulating layer disposed on the substrate in the first area and the second area and interposed between the substrate and the first organic insulating layer,
wherein the inorganic insulating layer includes a first portion located between the first organic insulating layer and the hole and a second portion located between the first portion and the hole, and a thickness of the second portion is less than a thickness of the first portion.
